(19) United States
(12) Patent Application Publication
(10) Pub. No.: US 2024/0126510 A1
(43) Pub. Date: Apr. 18, 2024

(54) METHOD AND SYSTEM FOR WAVE-BASED COMPUTATION

(71) Applicant: Calective LLC, Escondido, CA (US)

(72) Inventor: Lydell Aaron, Asheville, NC (US)

(21) Appl. No.: 18/475,007

(22) Filed: Sep. 26, 2023

Related U.S. Application Data
(60) Provisional application No. 63/377,906, filed on Sep. 30, 2022.
(60) Provisional application No. 63/497,108, filed on Apr. 19, 2023.

(51) Int. Cl. G06F 7/72; H03B 28/00

(52) U.S. Cl. CPC G06F 7/721; H03B 28/00

(57) ABSTRACT

Methods and systems for wave-based computation are provided. In one aspect, a wave-based computer includes an input circuit configured to receive a dividend and generate a plurality of prime waves and a dividend wave based on the received dividend, and a transmission circuit configured to receive the prime waves and the dividend wave from the input circuit. The wave-based computer further includes an output circuit configured to receive the prime waves and the dividend wave from the transmission circuit, detect zero-crossings of each of the prime waves and the dividend wave, and determine prime factors of the dividend based on the detected zero-crossings.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57. This application claims priority to and the benefit of Provisional Application No. 63/377,906 filed on Sep. 30, 2022 in the U.S. Patent and Trademark Office and claims priority to and the benefit of Provisional Application No. 63/497,108 filed on Apr. 19, 2023 in the U.S. Patent and Trademark Office, the entire contents of each of which are incorporated herein by reference.

### BACKGROUND

### Technological Field

The described technology generally relates to wave-based computers.

### Description of the Related Technology

Traditional computers use binary logic to compute various functions. For many complex computations, the binary instructions required to implement the complex computations may require computation times that increase more quickly as the number of inputs to the computations increases.

### SUMMARY

The embodiments disclosed herein each have several aspects, no single one of which is solely responsible for the disclosure's desirable attributes. Without limiting the scope of this disclosure, its more prominent features will now be briefly discussed. After considering this discussion, and particularly after reading the section entitled “Detailed Description,” one will understand how the features of the embodiments described herein provide advantages over existing systems, devices, and methods for digital computations that perform a variety of instructions, such as fetch-and-store or fetch-and-decode instructions.

One aspect is to provide alternative computational systems that do not increase in time in the same way as traditional computers. Another aspect is a wave-based computer, comprising: an input circuit configured to receive a dividend and generate a plurality of prime waves and a dividend wave based on the received dividend; a transmission circuit configured to receive the prime waves and the dividend wave from the input circuit; and an output circuit configured to: receive the prime waves and the dividend wave from the transmission circuit, detect zero-crossings of each of the prime waves and the dividend wave, and determine prime factors of the dividend based on the detected zero-crossings.

In some embodiments, the input circuit comprises: a plurality of prime oscillators, each of the prime oscillators configured to generate a corresponding one of the prime waves having a frequency corresponding to a prime number, and a dividend oscillator configured to be tuned to generate the dividend wave to have a frequency that corresponds to the dividend.

In some embodiments, the input circuit further comprises: a plurality of phase adjustors configured to adjust a phase of a corresponding one of the prime oscillators and the dividend oscillator.

In some embodiments, adjusting the phase of the corresponding one of the prime oscillators and the dividend oscillator comprises rotating or inverting the phase.

In some embodiments, the transmission circuit comprises: a plurality of transmission line paths, each of the transmission line paths including a conductive path that couples a corresponding one of the prime oscillators and the dividend oscillator to the output circuit.

In some embodiments, the transmission circuit further comprises: a plurality of gyrators, each of the gyrators configured to convert a corresponding one of the prime waves and the dividend waves from a voltage wave to a current wave.

In some embodiments, the output circuit comprises: a plurality zero-crossing detectors configured to receive a corresponding one of the prime waves and the dividend wave and generate a zero-crossing signal indicating that the corresponding one of the prime waves and the dividend wave has a value of substantially zero.

In some embodiments, each of the zero-crossing signals has a predetermined shape including one or more of the following: a rectangular pulse, a cosine squared pulse, a Dirac pulse, a sine pulse, a Ricker pulse, a hypergeometric pulse, or a Gaussian pulse.

In some embodiments, the output circuit further comprises: a plurality of registers, each of the registers configured to receive a corresponding one of the zero-crossing signals and increment a value in the register in response to the received zero-crossing signal.

In some embodiments, the output circuit is further configured to determine the prime factors of the dividend based on a first one of the registers corresponding to a prime wave incrementing at substantially the same time a second one of the registers corresponding to the dividend wave incrementing.

Yet another aspect is a method for quantum computation comprising: receiving an input dividend integer; generating a dividend wave using a dividend oscillator, the dividend wave having a frequency that represents the input dividend integer; generating a plurality of prime waves using a plurality of prime oscillators, each of the prime waves having a frequency that represents a corresponding prime number; detecting, using a plurality of zero-crossing detectors, zero-crossings of the dividend wave and each of the prime waves; and determining prime factors of the dividend integer based on the detected zero-crossings.

In some embodiments, the method further comprises: adjusting, using a plurality of phase adjustors, a phase of each of the dividend wave and the prime waves.

In some embodiments, the method further comprises: transmitting the dividend wave and each of the prime waves to the zero-crossing detectors using a plurality of transmission line paths.

In some embodiments, the method further comprises: converting the dividend wave and each of the prime waves from a voltage wave to a current wave using a plurality of gyrators.

In some embodiments, the method further comprises: generating, using the zero-crossing detectors, a zero-crossing signal indicating that the corresponding one of the prime waves and the dividend wave has a value of substantially zero.

In some embodiments, each of the zero-crossing signals has a predetermined shape including one or more of the following: a rectangular pulse, a cosine squared pulse, a Dirac pulse, a sinc pulse, a Ricker pulse, a hypergeometric pulse, or a Gaussian pulse.

Still yet another aspect is a non-transitory computer readable recording medium comprising instructions, when executed by a wave-based computer, cause the wave-based computer to: receive an input dividend integer; generate a dividend wave using a dividend oscillator, the dividend wave having a frequency that represents the input dividend integer; generate a plurality of prime waves using a plurality of prime oscillators, each of the prime waves having a frequency that represents a corresponding prime number; detect, using a plurality of zero-crossing detectors, zero-crossings of the dividend wave and each of the prime waves; and determine prime factors of the dividend integer based on the detected zero-crossings.

In some embodiments, the instructions further cause the wave-based computer to: adjust, using a plurality of phase adjustors, a phase of each of the dividend wave and the prime waves.

In some embodiments, the instructions further cause the wave-based computer to: transmit the dividend wave and each of the prime waves to the zero-crossing detectors using a plurality of transmission line paths.

In some embodiments, the instructions further cause the wave-based computer to: convert the dividend wave and each of the prime waves from a voltage wave to a current wave using a plurality of gyrators.

In some embodiments, the instructions further cause the wave-based computer to: generate, using the zero-crossing detectors, a zero-crossing signal indicating that the corresponding one of the prime waves and the dividend wave has a value of substantially zero.

Another aspect is a wave-based computer, comprising: an input signal processor configured to receive a dividend and generate a plurality of prime waves and a dividend wave based on the received dividend; a transmission circuit configured to receive the prime waves and the dividend wave from the input signal processor; and an output signal processor configured to: receive the prime waves and the dividend wave from the transmission circuit, detect zero-crossings of each of the prime waves and the dividend wave, and determine prime factors of the dividend based on the detected zero-crossings.

Any of the features of an aspect is applicable to all aspects identified herein. Moreover, any of the features of an aspect is independently combinable, partly or wholly with other aspects described herein in any way, e.g., one, two, or three or more aspects may be combinable in whole or in part. Further, any of the features of an aspect may be made optional to other aspects. Any aspect of a method can comprise another aspect of a system. Furthermore, any aspect of a system can be configured to perform a method of another aspect.

### BRIEF DESCRIPTION OF THE DRAWINGS

FIG. 1A is an embodiment of a wave-based computer according to aspects of this disclosure.

FIG. 1B is another embodiment of a wave-based computer according to aspects of this disclosure.

FIG. 1C is yet another embodiment of a wave-based computer according to aspects of this disclosure.

FIG. 1D is still yet another embodiment of a wave-based computer according to aspects of this disclosure.

FIG. 2A is an embodiment of reciprocal oscillators connected to transmission line paths in accordance with aspects of this disclosure.

FIG. 2B is an embodiment of a digital input programming an oscillator in accordance with aspects of this disclosure.

FIG. 2C is an embodiment of two reciprocal oscillators connected to a zero-cross detector in accordance with aspects of this disclosure.

FIG. 2D illustrates how a single signal can be decomposed into prime components.

FIG. 2E illustrates how a sinusoidal signal can be routed between input and output, based on turning on a diode by biasing positive and negative voltage.

FIG. 3A is a flowchart illustrating an example method for detecting prime factors using the wave-based computer in accordance with aspects of this disclosure.

FIG. 3B is a flowchart illustrating another example method for detecting prime factors using the wave-based computer in accordance with aspects of this disclosure.

FIG. 3C is a flowchart illustrating yet another example method for detecting prime factors using the wave-based computer in accordance with aspects of this disclosure.

FIG. 4A is one embodiment of the wave-based computer in accordance with aspects of this disclosure.

FIG. 4B provides a more detailed view of the wave-based computer of FIG. 4A in accordance with aspects of this disclosure.

FIG. 4C is one example of a wave-based reactive computer in accordance with aspects of this disclosure.

FIG. 5 is another embodiment of a zero-cross detector in accordance with aspects of this disclosure.

FIG. 6 is yet another embodiment of a zero-cross detector in accordance with aspects of this disclosure.

FIG. 7 is still yet another embodiment of a zero-cross detector in accordance with aspects of this disclosure.

FIG. 8 is a flowchart illustrating an example method for calibrating a wave-based computer in accordance with aspects of this disclosure.

FIG. 9 illustrates the dividend and the synchronization wave in accordance with aspects of this disclosure.

FIG. 10 shows a prime wave with a frequency of 11 Hz, representing the prime number 11.

FIG. 11 shows a prime wave with a frequency of 7 Hz, representing the prime number 7.

FIG. 12 shows a prime wave with a frequency of 5 Hz, representing the prime number 5.

FIG. 13 shows a prime wave with a frequency of 3 Hz, representing the prime number 3.

FIG. 14 shows a prime wave with a frequency of 2 Hz, representing the prime number 2.

FIG. 15 illustrates the superposition of each of the individual waves from FIGS. 9-14.

FIG. 16 illustrates measurement uncertainty associated with the detection of a zero-crossing in accordance with aspects of this disclosure.

FIGS. 17A-17O show sinusoidal waveforms with a zero-crossing detection impulse overlayed in accordance with aspects of this disclosure.

FIG. 18 illustrates a user interface for the wave-based computer in accordance with aspects of this disclosure.

FIG. 19 illustrates a quantum object which can receive a pair of input waveforms which contain spectra, absorb some of the waveform spectra, and generate an output spectra, and reflect a portion of the output spectra.

FIG. 20 illustrates a more detailed embodiment of the quantum object including a plurality of internal oscillators.

FIG. 21 illustrates how a first quantum object and a second quantum object can interact.

FIG. 22 illustrates an embodiment showing collections of quantum objects.

FIG. 23 illustrates an example of wave pulse oscillation (“wavelet”) containing a real and imaginary part, which can be employed as the input, the output, and/or the reflected output in accordance with aspects of this disclosure.

FIG. 24 shows an example of three component steady state sine waves and their summation or superposition, represented by the line.

FIG. 25 shows an example of three component steady state sine waves and their multiplication or product, represented by the line.

### DETAILED DESCRIPTION

The described technology generally relates to a method and system for wave-based computers. In some implementations, the wave-based computer can be implemented to accomplish or achieve quantum computation. For example, the system may include a coupled oscillator quantum computer. As used herein, a quantum computer may generally refer to any computer device that uses the waves properties of quantum mechanics in order to perform computations including, for example, the properties of waves including superposition, interference, and/or entanglement, as well as properties of wave energy absorption, emission or transmission, and reflection.

### Wave-Based Prime Factorization Computer

One computational task that is complex for traditional computers is finding prime factors of an integer. For example, the complexity of many prime factorization algorithms may be O((n)). The complexity of algorithms may be expressed using Big-O notation “O(f(n))”, where the runtime is expressed as a function of the number of inputs n to the algorithm. A constant time algorithm can be expressed by as O(1), while a linear time algorithm would be expressed as O(n). In the case of prime factorization algorithms having O((n)), as the size of the input integer (generally referred to as the “dividend” herein) increases, the time required to find the prime factors at a rate proportional to the square root of the size of the dividend. For very large integers, this can make finding prime factors very time-consuming.

One application for calculating prime factors is in cryptography. For example, many cryptographic protocols are based on the difficulty of factoring large integers. Thus, improvements in the time required to factor integers could be used to transform cryptography, for example, by breaking current cryptographic protocols with specialized prime factoring circuitry. Wave-based computers in accordance with aspects of this disclosure can perform computations in the is units of a stationary or traveling wave, O(2π).

### Real-Time Wave-Based Relational Dynamics Computer

One computational task that can involve multiple computational cycles for traditional computers is the calculation of sine and cosine functions. For example, sine and cosine functions generally use numerical approximations methods in order to compute a single result, and at times may use lookup tables to increase performance but at the expense of accuracy. Sine and cosine functions are often and extensively used for wave-based computations in math, physics, science, and engineering.

Further applications for the disclosed technology include modeling and simulating relational dynamics between two or more reactive systems, or dynamics between groups and clusters of reactive systems. As used herein, a reactive system may generally refer to a system that reacts to one or more input signals each having an input frequency or wavelength. The output of a reactive signal can be one or more output signals each having an output frequency or wavelength.

Examples of reactive systems include metals exhibiting the photoelectric effect where metals can emit electrons when hit with an electromagnetic wave, such as light, of a specific frequency or wavelength. Another example includes neurons which can accept an oscillatory or wave input from other neurons or external source, and then output oscillatory or wave signals in order to communicate with neighboring neurons. Similarly, humans can be considered a reactive system since humans can sense, feel, and emit emotions when they perceive a photon, which is light, phonons, or other wave phenomena such as music, voice, touch or taste, of a specific frequency or wavelength, and can thus may be called reactive systems. Other reactive systems include atoms, molecules, and subatomic particles. Simulating reactive systems can b e used for discovering new molecular properties, and/or simulating or modeling human reactions to law, governance, taxation, and policy.

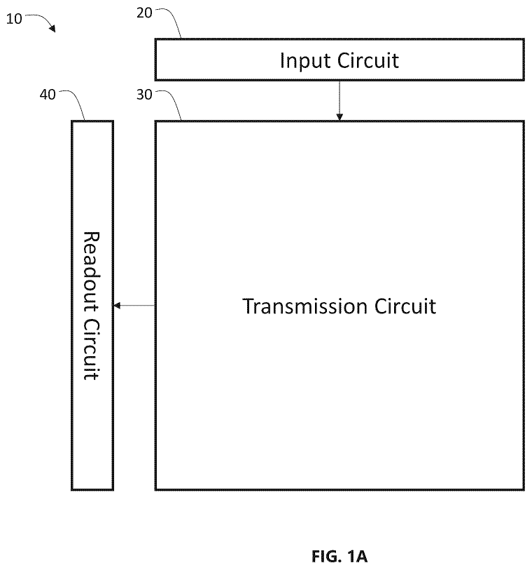

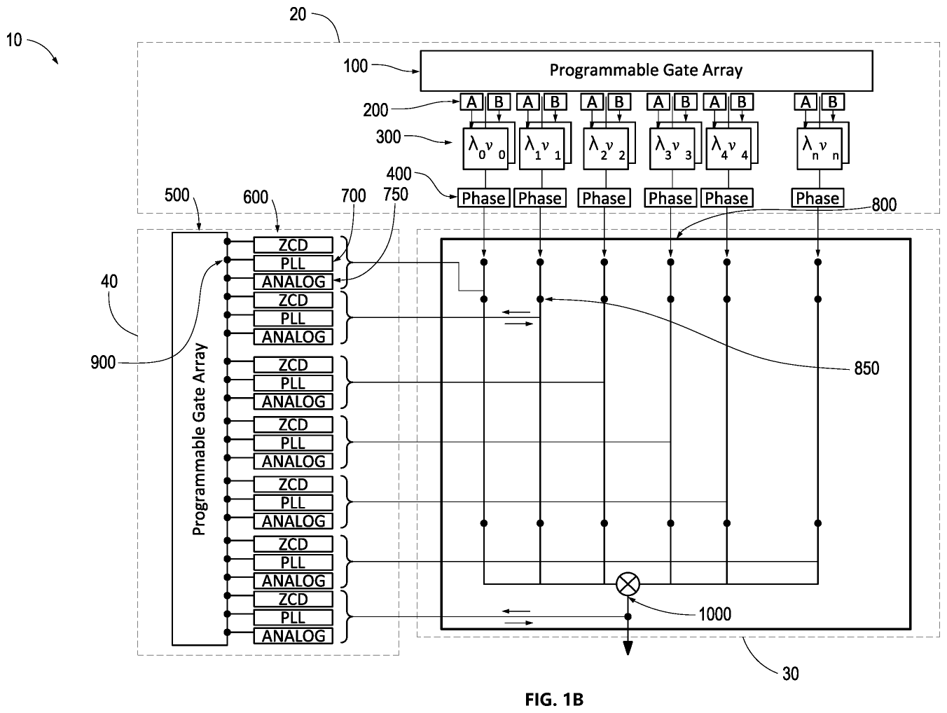

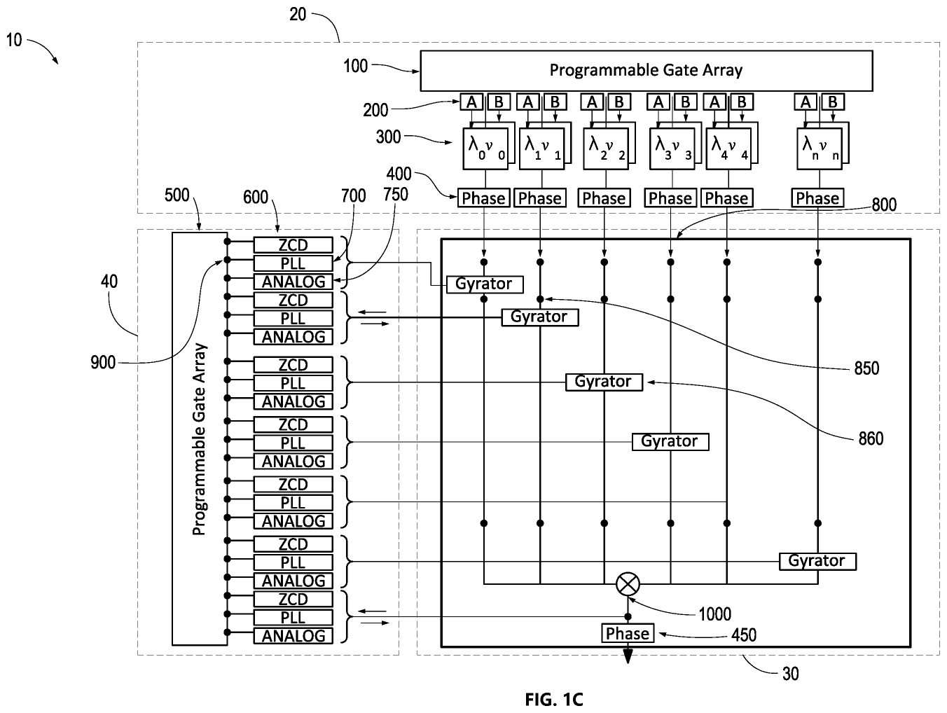

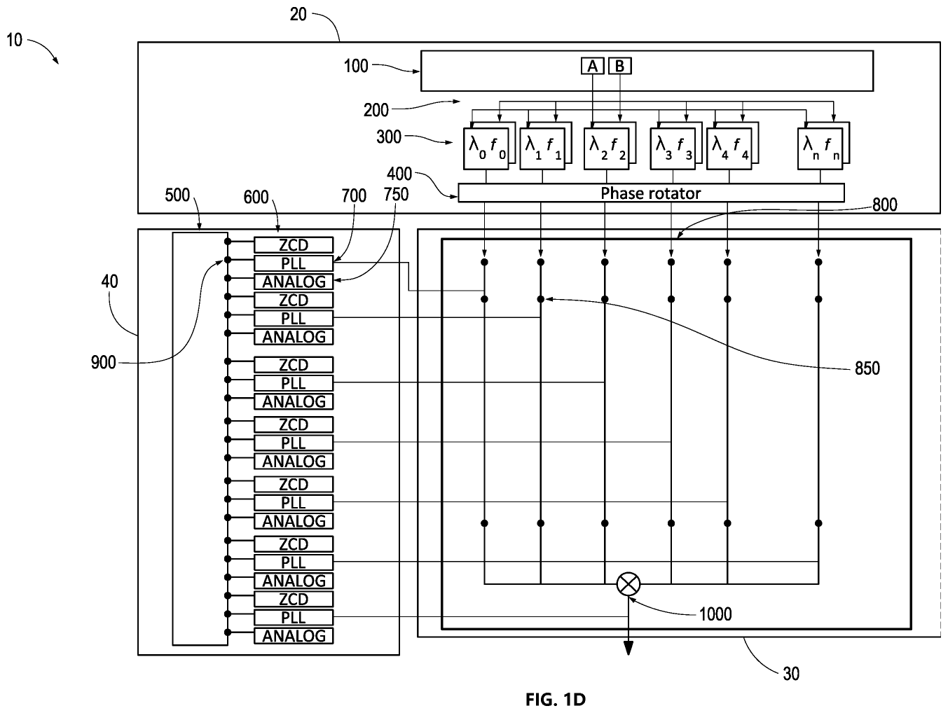

FIG. 1A is an embodiment of a wave-based computer 10 according to aspects of this disclosure. The wave-based computer 10 comprises an input circuit (or an input processor) 20, a transmission circuit 30, and a readout circuit or output circuit (or output processor) 40. At least one of the input circuit 20 or the output circuit 40 can be implemented with software, hardware, or a combination thereof. The input circuit 20 is configured to receive an input to be processed by the wave-based computer 10. When configured to find the prime factors of a dividend, the input circuit 20 can be configured to receive the dividend to be factored.

The input circuit 20 is configured to provide a representation of the dividend to the transmission circuit 30. In some embodiments, the input circuit 20 is also configured to provide representations of each of the prime numbers which could potentially be the prime factors of the dividend to the transmission circuit 30. As described herein, the dividend and each of the prime numbers may be represented by waves, each of which has a frequency that corresponds to either the dividend or the prime number.

The transmission circuit 30 is configured to connect the input circuit input circuit 20 to the readout circuit 40. As described in detail herein, the transmission circuit 30 provides connections between the waves received from the input circuit 20 to corresponding circuits within the readout circuit 40 that are configured to count and detect the timings of the “zero-crossings” of the waves. As used herein, a zero-crossing refers to the point in time at which the value of a wave is zero. Zero-crossing may also include information related to the direction of the wave (e.g., whether the wave is crossing from positive to negative, or vice versa).

The readout circuit 40 is configured to determine which of the waves representing the prime numbers is a factor of the dividend based at least in part on the timings of the detected zero-crossings and/or the number of zero-crossings for the waves representing the prime numbers and the wave representing the dividend.

FIG. 1B is another embodiment of a wave-based computer 10 according to aspects of this disclosure. The input circuit 20 includes an input controller 100, one or more input waveforms 200, a plurality of oscillators 300, and a plurality of phase adjustors 400 (also referred to as phase rotators).

The transmission circuit 30 includes a plurality of transmission line paths 800. Each of the plurality of transmission line paths 800 can be formed with one or more conductive paths 850. The transmission circuit 30 can further include a summing junction 1000.

The readout circuit 40 includes a plurality of zero-crossing detectors 600, a plurality of optional phase locked loops (PLLs) 700, a plurality of optional analog computing blocks 750, and a read-out controller 500. The read-out controller 500 can be configured to receive outputs from each of the zero-crossing detectors 600, PLLs 700, analog computing blocks 750, and a plurality of detector signal lines 900. In some implementations, the PLLs 700 can be configured for frequency and phase detection.

In some implementations, one or more of the input controllers 100 and the read-out controller 500 can be embodied as a programmable gate array. The input controller 100 can be configured to receive a dividend as an input, for example, in the form of a digital integer. Thus, the input controller 100 can be configured to be connected to an external circuit, such as a traditional computer, a user interface, and/or any other circuit configured to provide a dividend to the input controller 100. The input controller 100 can be configured to program one of the oscillators 300 (which can be referred to as the dividend oscillator 300) with a value corresponding to the input dividend integer, for example, by providing an input waveform 200 representing the integer to the dividend oscillator 300.

The plurality of oscillators 300 can include the dividend oscillator 300 and a plurality of prime oscillators. The wave-based computer 10 can include one prime oscillator 300 for each prime number that the wave-based computer 10 can use as a divisor for an input dividend. Each of the prime oscillators 300 can be configured to have a frequency based on the corresponding prime number. In some embodiments, the number 1 is represented with a 1 Hz frequency, and each prime number is represented by the same number of Hz (e.g., 2 is represented by 2 Hz, 3 is represented by 3 Hz, 5 is represented by 5 Hz, etc.). The dividend oscillator 300 is configured to be tuned by the input waveform 200 received from the input controller 100 such that the frequency of the wave generated by the dividend oscillator 300 corresponds to the dividend input received by the input controller 100. In some embodiments, the oscillators 300 are configured to generate wave having the shape of a sine wave, although other embodiments are also possible. Because the frequency of the wave associated with the number 1 may be the lowest frequency wave, all other waves can be designed to have a zero crossing at 0, π, and 2π radians of the wave associated with the number 1. Thus, the wave associated with the number 1 may be considered a synchronization wave.

Each of the phase adjustors 400 and 450 can be configured to adjust (e.g., slide) the phase of the wave produced by a corresponding one of the oscillators 300 such that each wave provided to the transmission circuit 30 is synchronized with the 1 Hz wave. For example, the phase adjustors 400 and 450 may be configured to slide the phase of the corresponding wave to the left or right (e.g., by increasing or decreasing the frequency of the wave). In some embodiments, the phase adjustors 400 may also be configured to adjust a phase polarity (e.g., by inverting the polarity) of the corresponding wave. For example, the phase adjustors 400 may be configured to flip the wave upside down to invert the polarity of the wave. The waves are then provided to the readout circuit 40 via the plurality of transmission line paths 800 of the transmission circuit 30.

Each of the zero-crossing detectors 600 is configured to receive a corresponding one of the waves and generate a signal when the wave crosses the x-axis (e.g., when the wave has a value of zero). In certain embodiments, the zero-crossing detectors 600 are configured to output a pulse having a predetermined shape. Depending on the implementation, the pulse shape may be a rectangular pulse, a cosine squared pulse, a Dirac pulse, a sinc pulse, a Ricker pulse, a hypergeometric pulse, or a Gaussian pulse. In some embodiments, the zero-crossing detectors 600 may generate a Dirac pulse and/or a hypergeometric pulse for certain applications.

The read-out controller 500 can include a plurality of registers (or any other digital counter), each of which can correspond to one of the zero-crossing detectors 600. The zero-crossing detector 600 can be configured to count wave k pulses. In response to receiving a detection pulse from the corresponding zero-crossing detector 600, a register can increment, thereby counting the number of zero-crossings of the corresponding wave. The read-out controller 500 can also include a zero-crossing timing detector configured to determine that the register coupled to the dividend wave (e.g., a dividend register) increments at the same time as one or more of the registers corresponding to the prime waves. As discussed herein, if the wave for a prime number crosses zero at the same time as the wave for the dividend within one period of the 1 Hz wave, then the read-out controller 500 can determine that the prime number is in common with the dividend, or a common factor of the dividend. Once all of the prime factors have been identified, the read-out controller 500 can output a representation of the prime factors of the dividend, for example, to an external circuit. This may involve using one or more summers to add together each of the identified prime numbers to generate a representation of all of the prime factors. The external circuit may be embodied in a traditional computer, a user interface, and/or any other circuit configured to receive the prime factors from the wave-based computer 10 and may or may not be the same external circuit that provides the dividend to the input controller 100.

FIG. 1C is yet another embodiment of a wave-based computer 10 according to aspects of this disclosure. The wave-based computer 10 of FIG. 1C is substantially the same as the wave-based computer 10 of FIG. 1B, with the inclusion of a plurality of gyrators 860. The gyrators 860 are configured to convert a voltage wave received from a corresponding one of the oscillators 300 to a current wave. The zero-crossing detectors 600 of the FIG. 1C embodiment are configured to detect zero-crossings of the current waves, rather than that of voltage waves as in FIG. 1B. For certain applications, the wave-based computer 10 may use current waves instead of voltage waves since there may not be limits to the amplitude of current waves that may be applicable to voltage waves. The FIG. 1C embodiment may also include a phase adjustor 450 within the transmission circuit 30, which has the effect of inverting the polarity of all frequencies within the final superimposed outgoing wave if any post-adjustment is required.

Gyrators are electronic circuits which can be used to synthesize inductors used in the oscillators 300. In some implementations, inductors constructed using gyrators may be more compact and/or more precise than inductors constructed using other technologies. Inductors with one or more of the following characteristics: frequencies below hundreds of kilohertz (e.g., below 100 kHz), substantially no magnetic sensitivity, with values of inductance L of 1 Henries and above, are desirable but may not be practical with coil-wound inductors because coil-wound inductors are relatively heavy, large, and reactive to magnetic interference. Gyrators are used as precision synthetic inductors with comparatively large inductance and compact enough to fit onto an integrated circuit package when compared to coil-wound inductors.

FIG. 1D is still yet another embodiment of a wave-based computer 10 according to aspects of this disclosure. The wave-based computer 10 of FIG. 1C is substantially the same as the wave-based computer 10 of FIG. 1B, except the input waveforms 200 are repositioned and consolidated within the input controller 100 and that the plurality of phase adjustors 400 may be replaced with a single phase rotator 400. The consolidation of the input waveforms 200 in the input controller 100 can enable the use of a signal in the form of a wavelet containing a superposition of a plurality of frequencies. In addition, using a single phase rotator 400 can enable the shifting and/or inverting the polarity of all frequencies within the wavelet.

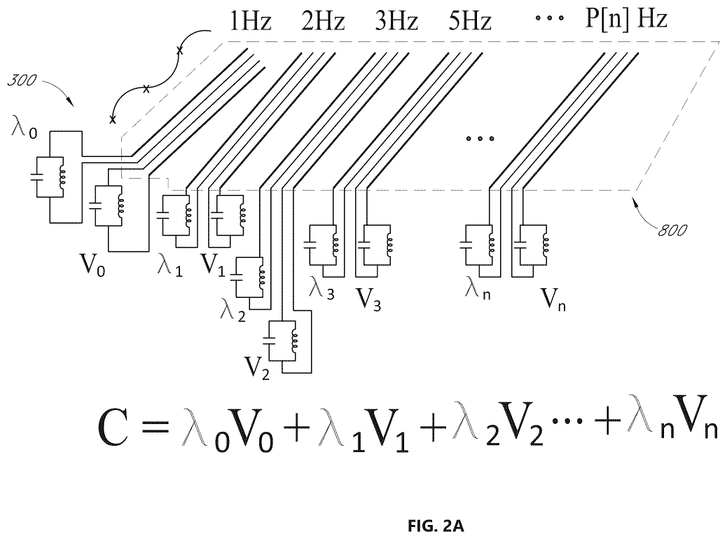

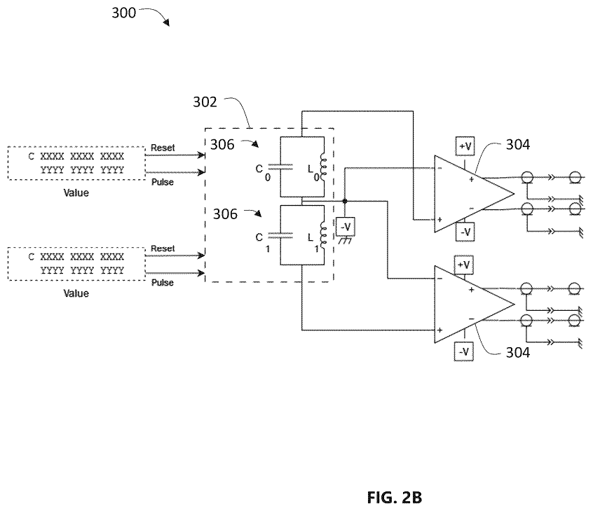

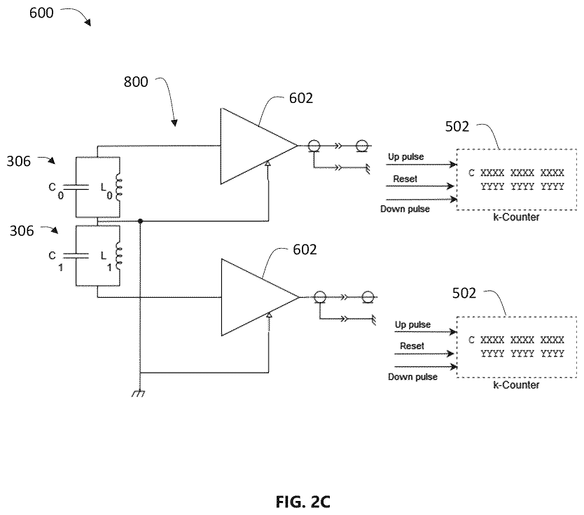

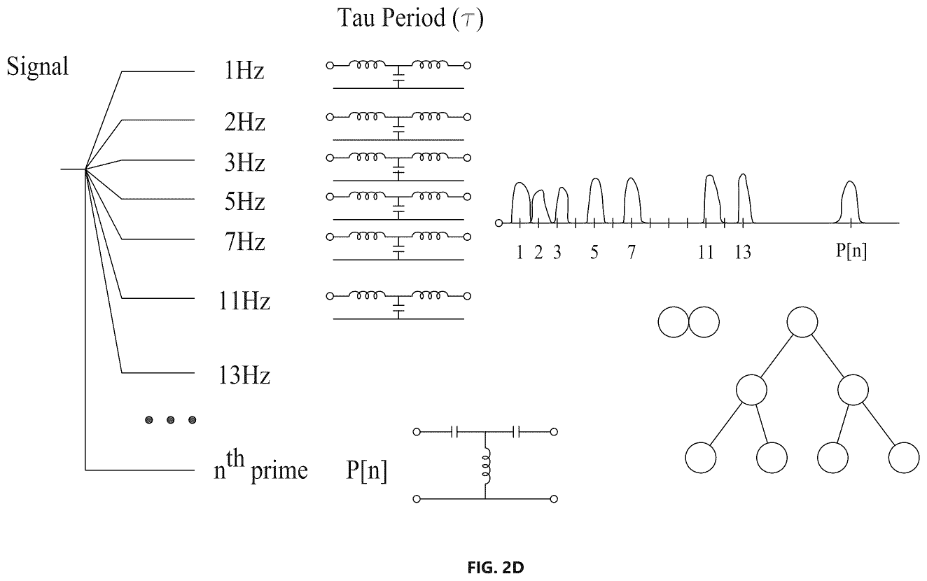

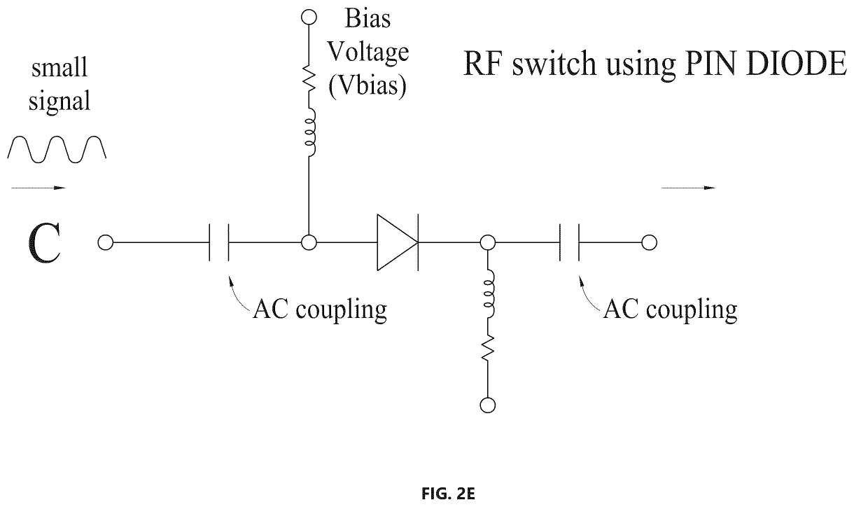

FIG. 2A is an embodiment of the transmission line paths 800 in accordance with aspects of this disclosure. As illustrated in the figure, the transmission line paths 800 are connected to the oscillators 300. In certain embodiments, the conductive paths 850 forming the plurality of transmission line paths 800 can be formed of nanofibers. Nanofiber has a thin diameter of, for example, 1-2 nm, which can be thinner than current methods such as lithography. Thus, nanofibers may be configured to fully contain the signals received from the oscillators 300. The plurality of transmission line paths 800 may be configured to aid in creating an evanescent wave. As used herein, an evanescent wave may generally refer to a phenomena that occurs when the transmission path medium is narrower than the wavelength of the contained light or electromagnetic wave, resulting in a portion of the wave radiating outside the boundary of the transmission path (e.g., nanofiber). Having a portion of the wave radiating outside the boundary of the transmission path can enable external measurement of the wave.

FIG. 2B is an embodiment of an oscillator 300 in accordance with aspects of this disclosure. As shown in FIG. 2B, the oscillator 300 can include a resonant circuit 302 and one or more amplifiers 304. The resonant circuit can include one or more LC circuits 306 with two LC circuits 306 shown in FIG. 2B. Although two LC circuits 306 are shown in the embodiment of FIG. 2B, aspects of this disclosure are not limited thereto and the oscillator 300 may include a single LC circuit 306 and a single amplifier 304 in some embodiments. In other embodiments, three or more of each of the LC circuits 306 and the amplifiers 304 may be included. Thus, in certain embodiments, the oscillators 300 can be implemented by a bank of independent but synchronized inductor-capacitor (LC) type sinusoidal oscillators. One possible LC oscillator that can be employed is the Clapp oscillator design, however, other implementations are also possible. In some embodiments, it can be advantageous to use Clapp oscillators because Clapp oscillators can be used to generate a very clean sinusoidal wave, above other oscillators. Other sinusoidal oscillators may generate waves with harmonics which are extraneous frequencies at integer frequencies of the original frequency. Avoiding harmonics can be important in implementations where the wave-based computer 10 uses the frequencies for the functional purpose of analog computation, wave counting, division, and/or zero-crossing detection. In certain embodiments, the oscillators 300 can be implemented using any components that can generate sine waves including electronic and magnetic permittivity properties of a material. As described above, it can be advantageous to use sinusoidal oscillators that do not have harmonics at integer frequencies of the primary frequency.

The resonant circuit 302 is configured to generate a wave having a predefined shape (e.g., a sine wave). When the resonant circuit 302 is included in a prime oscillator 300, the resonant circuit 302 may be configured to generate the wave with a frequency that corresponds to a predetermined prime number. When the resonant circuit 302 is included in a dividend oscillator 300, the resonant circuit 302 can be tunable such that the generated wave has a frequency that corresponds to the input dividend. In some embodiments, the resonant circuit 302 can be tunable using input values including a reset signal and a pulse signal, although other input signals are also possible.

FIG. 2C is an embodiment of a zero-crossing detector 600 in accordance with aspects of this disclosure. As shown in FIG. 2C, the zero-crossing detector 600 can include one or more amplifiers 602 that are connected to one or more corresponding LC circuits 306 via the transmission line paths 800. The zero-crossing detectors 600 may be implemented via an operational amplifier analog electronic circuit, although other implementations may be used. As used herein, an operational amplifier generally refers to a two input device with one output. Operational amplifiers may be governed by the equation v=A(v1−v2), where v is the voltage signal output, A is the gain of the operational amplifier transfer function, v1 is the voltage of the first input source, and v2 is the voltage of the second input source. In some embodiments, one input source may be sinusoidal while the other input may be referenced to the zero-crossing line (e.g., may have a value of “zero”). The gain may be configured such that the voltage output is a pulse when the difference between the first and second input sources are within a specific tolerance of one another.

Each of the one or more amplifiers 602 of the zero-crossing detector 600 can be connected to a corresponding register 502. The corresponding register 502 can be configured to count the number of zero crossings of the wave within one period of the synchronization wave (e.g., the wave corresponding to the number 1). In some embodiments, the corresponding register 502 can be implemented as a digital wave k-counter. Because the zero-crossings for each of the prime waves generated by the prime oscillators 300 and the dividend wave generated by the dividend oscillator 300 can be detected within a single wavelength of synchronization wave, the prime factors can be determined with a substantially constant time (e.g., substantially proportional to the period or time interval of the synchronization wave). This is a significant advantage over other prime factoring algorithms which are at best able to find prime factors within a time of O(√(n)).

FIG. 2D illustrates how a single signal can be decomposed into prime components. The illustrated passive circuit filter is merely a conceptual illustration and is not necessarily implemented within the wave-based computer 10.

FIG. 2E illustrates how a sinusoidal signal can be routed and switched between input and output, based on a biasing positive and negative voltage. The amplitude of the input sinusoid can be designed to be less than the turn-on voltage of the diode. Applying a positive voltage bias and negative voltage bias tuns on the diode, allowing the sinusoid signal to pass through the diode. Depending on the embodiment, the sinusoidal routing circuit illustrated in FIG. 2E can be included in the plurality of transmission line paths 800, the one or more conductive paths 850, and/or the summing junction 1000 in order to route signals through the wave-based computer 10.

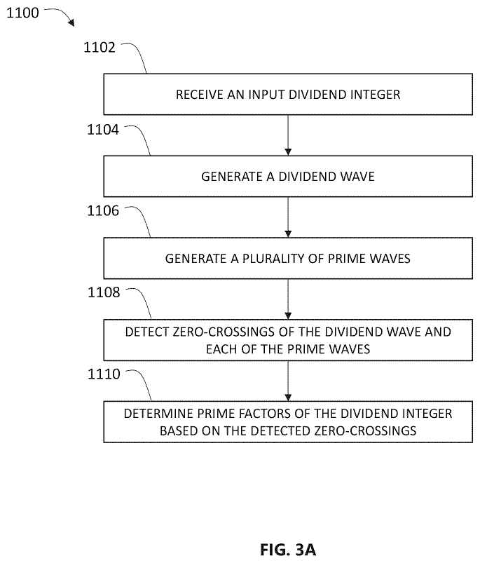

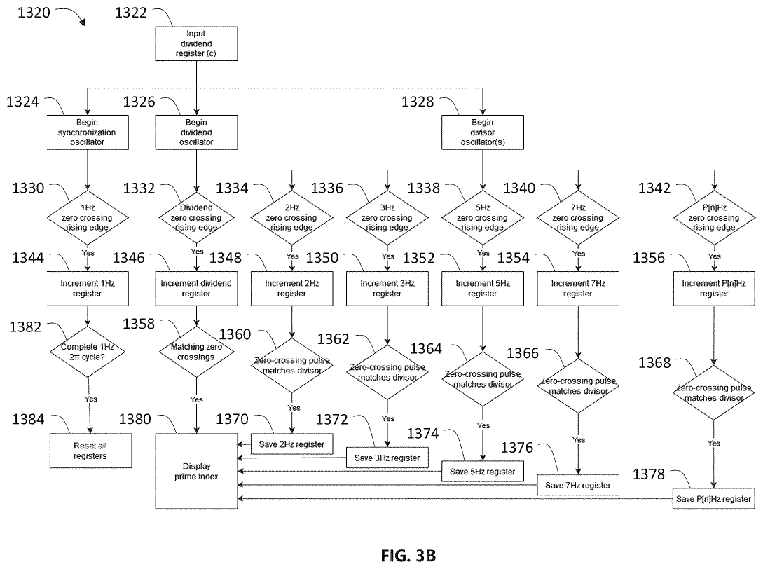

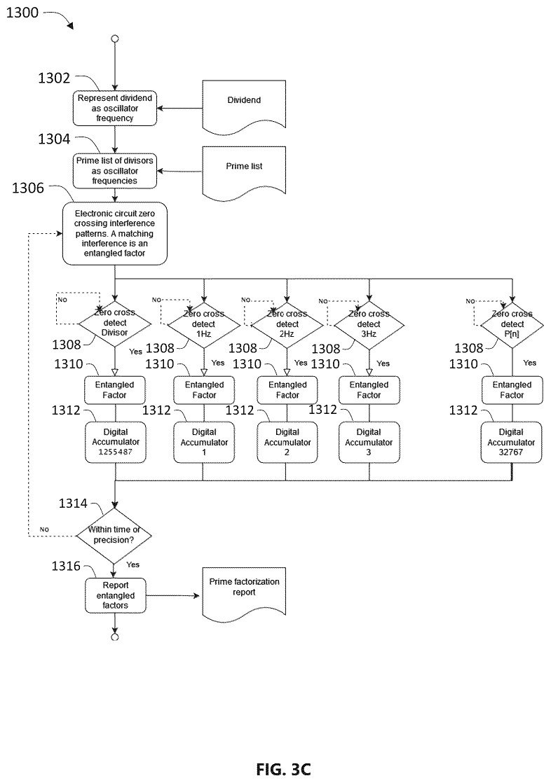

FIG. 3A is a flowchart illustrating an example method 1100 for detecting prime factors using the wave-based computer 10 in accordance with aspects of this disclosure. At block 1102, the method 1100 involves receiving an input dividend integer. For example, the input controller 100 can receive an input dividend from an external circuit.

At block 1104, the method 1100 involves generating a dividend wave using a dividend oscillator 300. The dividend wave can have a frequency that represents the input dividend integer. In some embodiments, the input controller 100 can tune the dividend oscillator 300 such that the waveform generated by the dividend oscillator 300 has a frequency that represents the dividend integer.

At block 1106, the method 1100 involves generating a plurality of prime waves using a plurality of prime oscillators 300. Each of the prime waves has a frequency that represents a corresponding one of the prime numbers. In some embodiments, the prime oscillators 300 can be tuned at the time of manufacturing to represent each of the prime numbers which can potentially be factors of the dividend integer. For example, each prime oscillator 300 can be tuned at a prime frequency from 2 Hz, 3 Hz, 5 Hz, 7 Hz, 11 Hz, 13 Hz, 17 Hz, 19 Hz, all the way up to the design limit of 2ⁿ-th prime P[2ⁿ] or n^{th} prime P[n]. The number of prime numbers represented by the prime oscillators 300 can be referred to as the dimension (D) of the wave-based computer 10.

At block 1108, the method 1100 involves detecting, using a plurality of zero-crossing detectors 600, zero-crossings of the dividend wave and each of the prime waves. The zero-crossings refer to the point at which each of the waves crosses the x-axis (e.g., has a value of zero).

At block 1110, the method 1100 involves determining prime factors of the dividend integer based on the detected zero-crossings. For example, the read-out controller 500 can be configured to identify a prime wave as a factor of the dividend when the prime wave and the dividend wave have zero-crossings that occur at substantially the same time (e.g., within a threshold difference). The read-out controller 500 can then output the prime factors for the dividend integer to an external circuit.

FIG. 3B is a flowchart illustrating yet another example method 1320 for detecting prime factors using the wave-based computer 10 in accordance with aspects of this disclosure. At block 1322, the method 1320 involves inputting a dividend c into a register of the input controller 100. At block 1324, the method 1320 involves beginning the synchronization oscillator 300. At block 1326, the method 1320 involves beginning the dividend oscillator 300. At block 1328, the method 1320 involves beginning the prime (e.g., divisor) oscillators 300.

At blocks 1330-1342, the method 1320 involves detecting a zero-crossing rising edge of the corresponding wave. In response to the zero-crossing detection, at blocks 1344-1356 the method 1320 involves incrementing a corresponding register.

At blocks 1358-1368, the method 1320 involves matching zero-crossings between the dividend waves and the divisor waves. When there is a match, at blocks 1370-1378, the method 1320 involves saving/incrementing a corresponding register. At block 1380, the method 1320 involves displaying the prime index. At block 1382, the method 1320 involves determining whether the synchronization signal has completed a full period. In response to the full period being complete, at block 1384 the method 1320 involves resetting all registers.

FIG. 3C is a flowchart illustrating yet another example method 1300 for detecting prime factors using the wave-based computer 10 in accordance with aspects of this disclosure. At block 1302, the method 1300 involves representing a dividend (or dividend) as an oscillator frequency based on an input dividend. At block 1304, the method 1300 involves representing a prime list of dividends as oscillator frequencies based on a prime list.

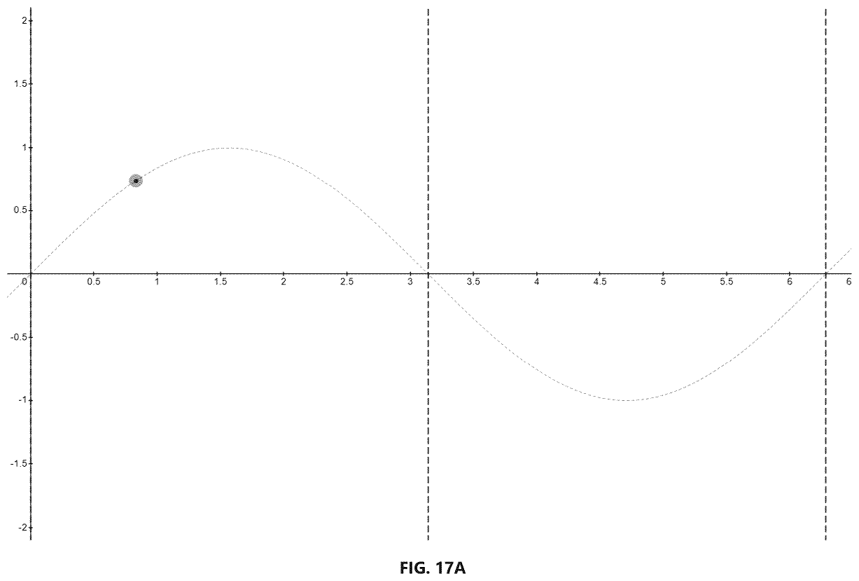

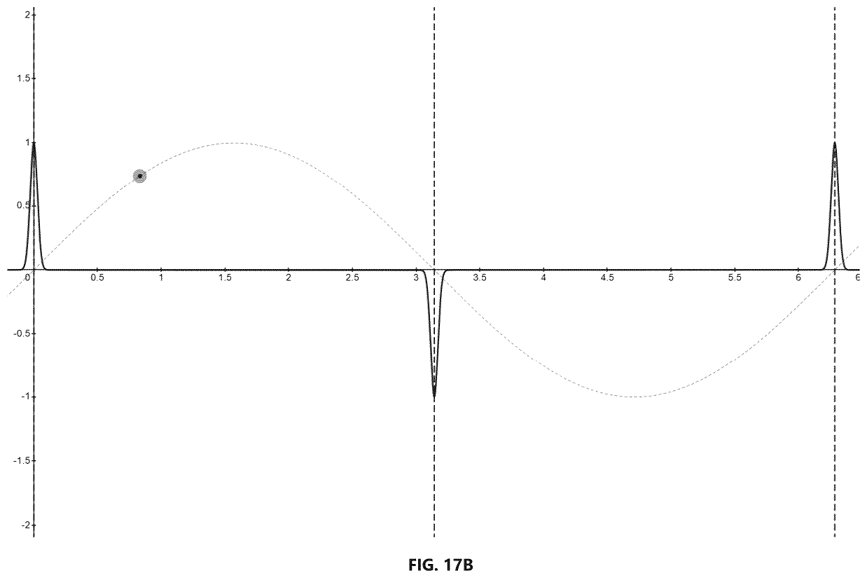

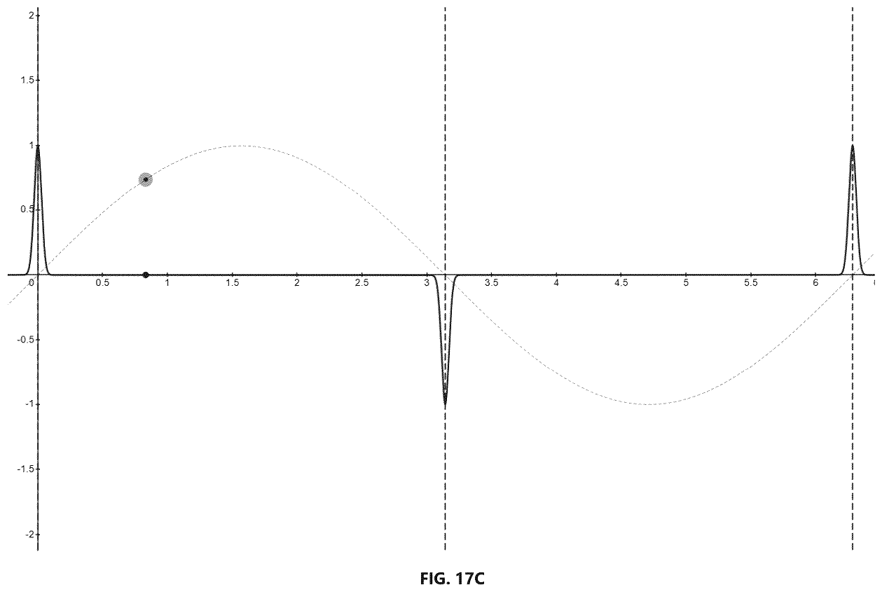

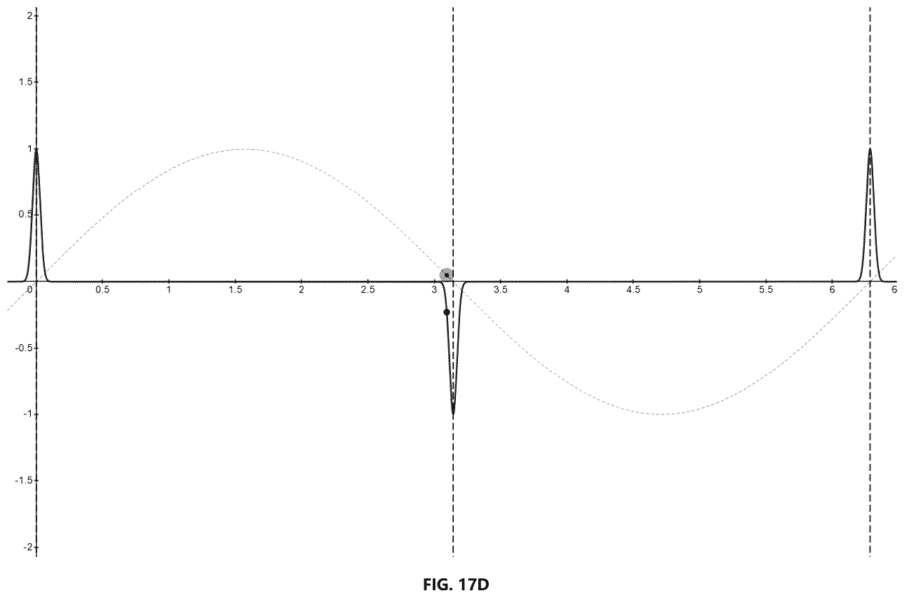

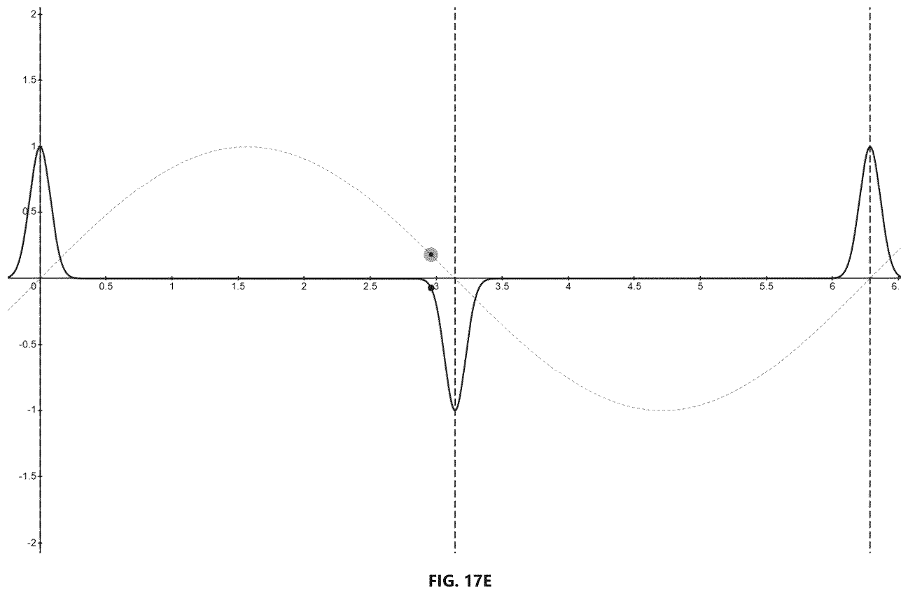

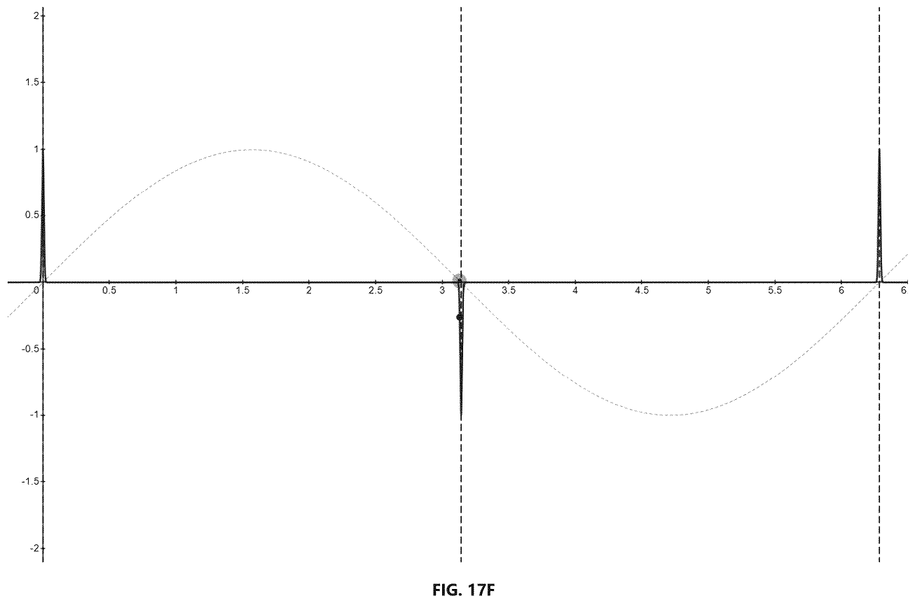

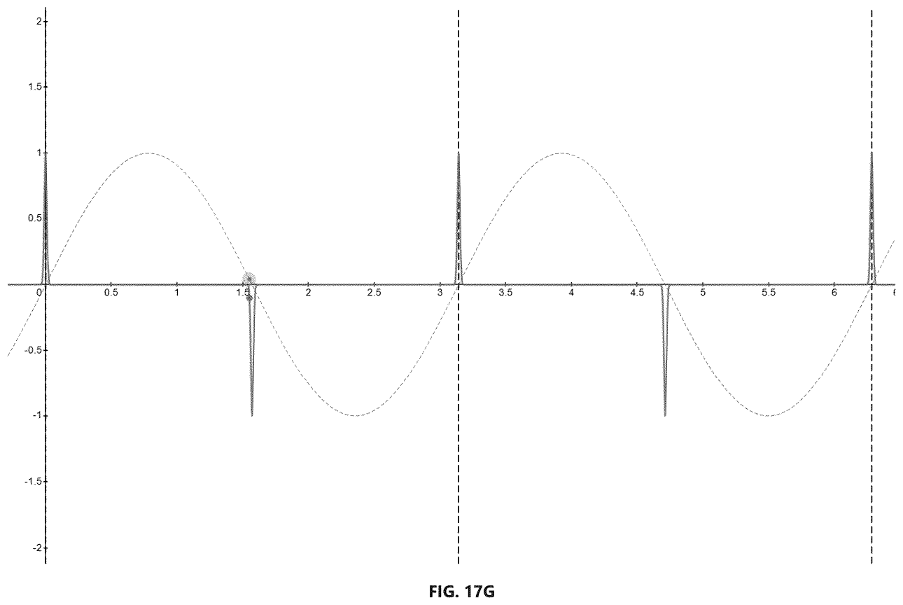

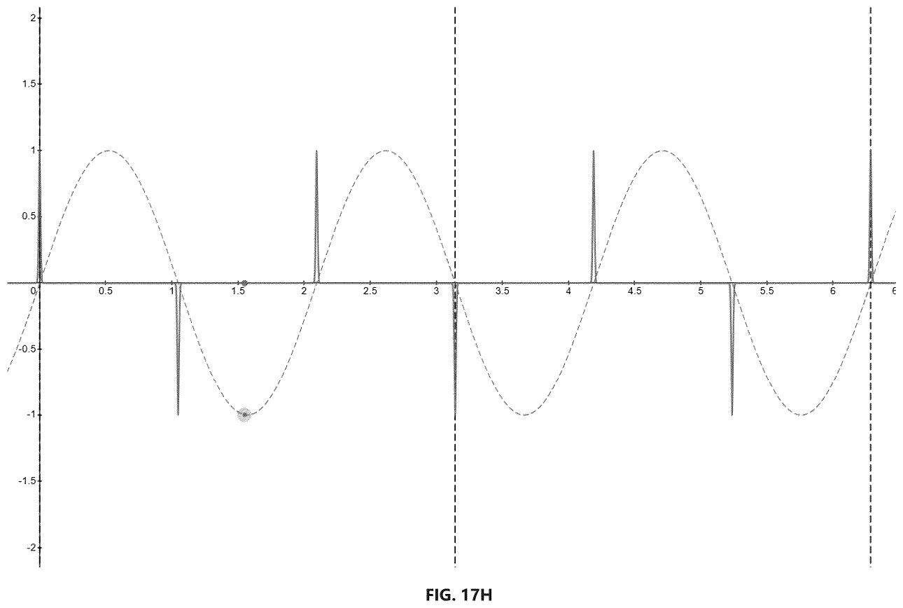

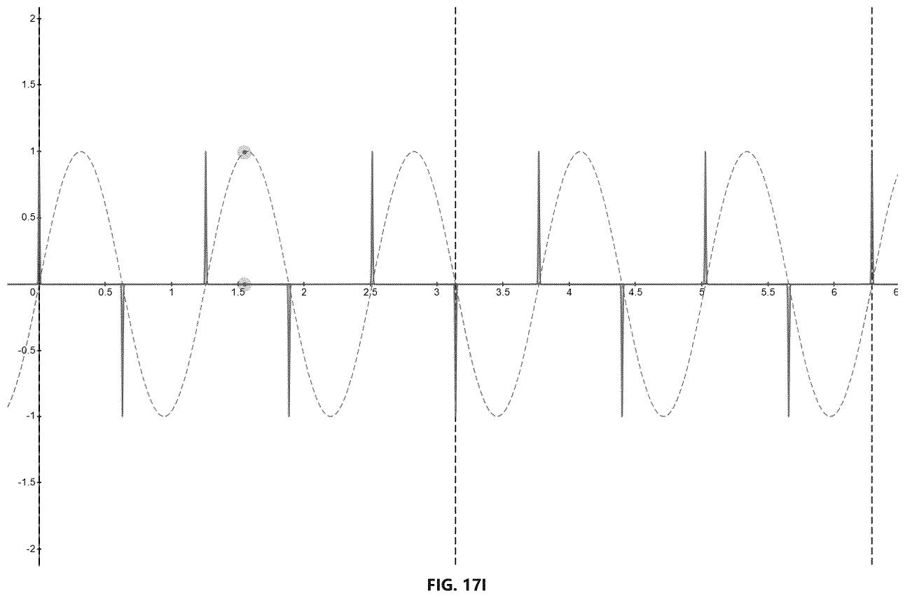

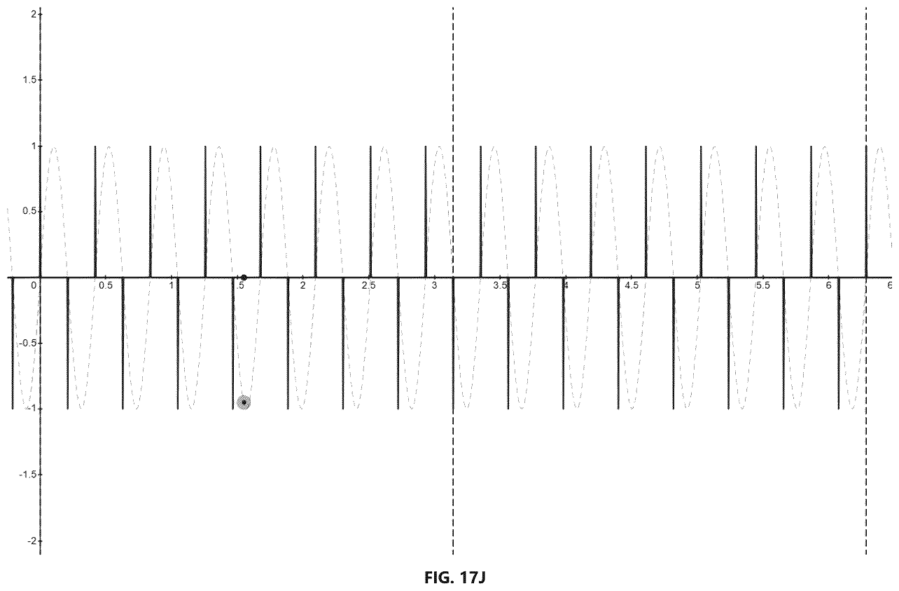

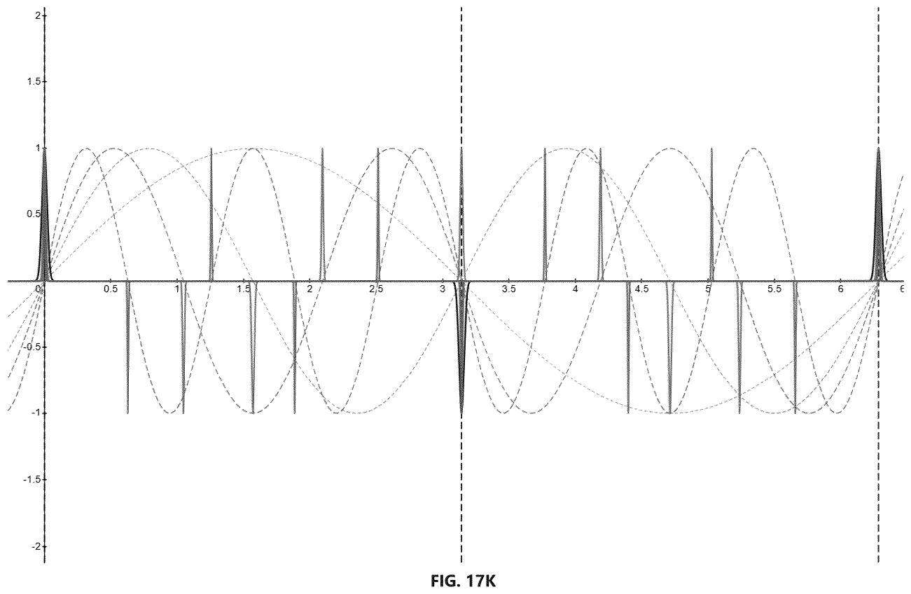

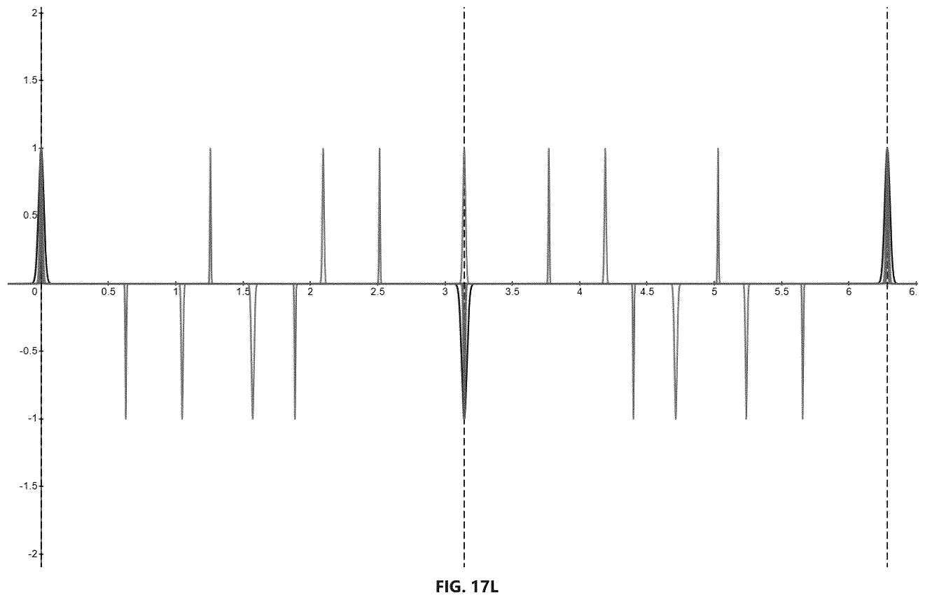

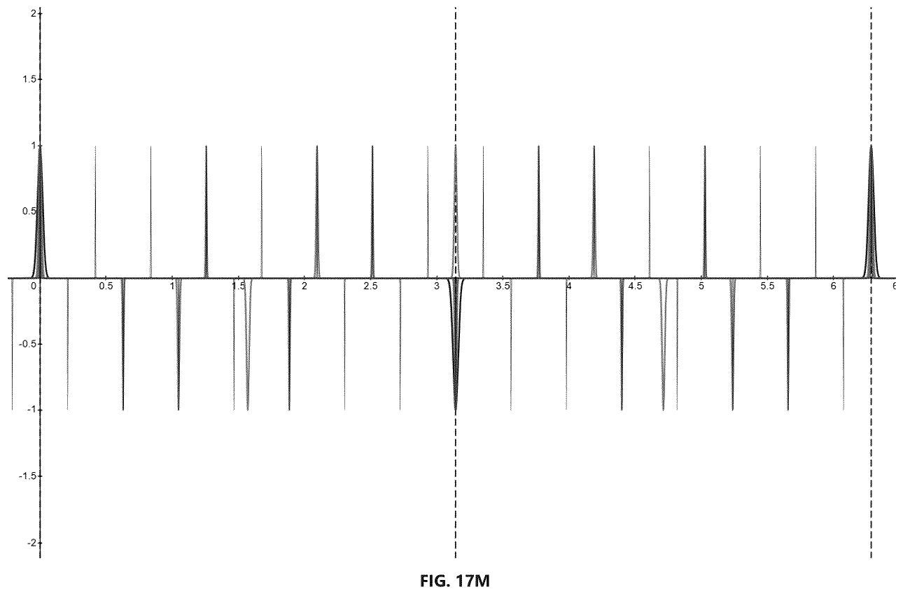

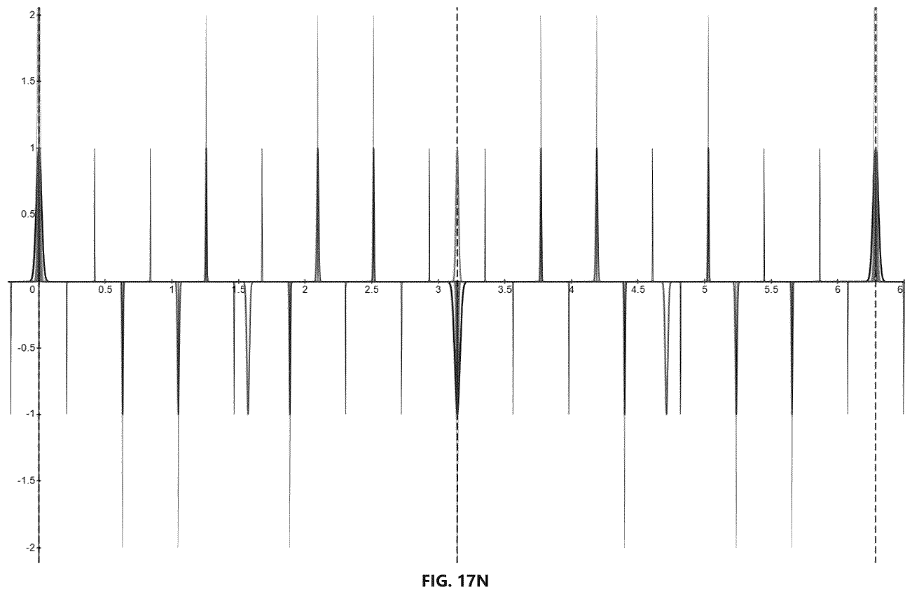

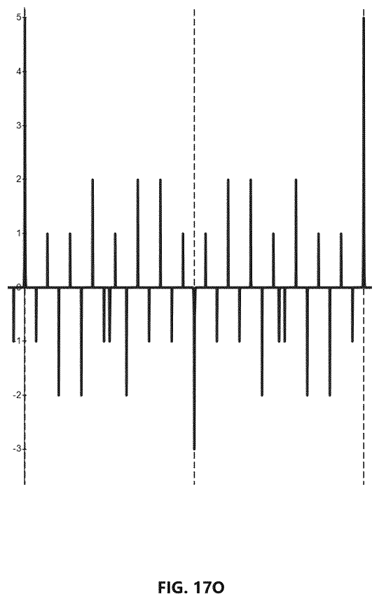

At block 1306, the method 1300 involves detecting electronic circuit zero crossing interference patterns. The dividend wave can be routed into a zero-crossing detector 600, which may generate a signal such as that shown in FIG. 17J. The divisor waves can also be routed into a zero-crossing detector zero-crossing detector 600, which can generate signals such as those shown in FIG. 17F, FIG. 17G, FIG. 17H, FIG. 17I to create a periodic zero-crossing pulse which can appear as an interference pattern as shown in FIG. 17M. A matching interference (e.g., see the example shown in FIG. 17N) can be an entangled factor in block 1306. At blocks 1308, each of the zero-crossing detectors 600 detects zero crossings for a corresponding one of the waves. At blocks 1310, the width of the zero-crossing detection pulse creates a small time and precision window and period of entanglement. At blocks 1312 a digital wave k-counter accumulates each integer value into a series of high-speed memory registers, which is illustrated in FIG. 2C block 502. At block 1314, each of the zero-crossing detection pulses which occur within the same time and precision (e.g., within a threshold difference) in conjunction with the digital accumulated values in each register, are compiled into a prime factorization report at block 1316, then the digital k-counter accumulators are cleared to zero at the beginning of the new 1 Hz cycle where the process repeats. At block 1316, the method 1300 involves reporting the prime factors in a prime factorization report.

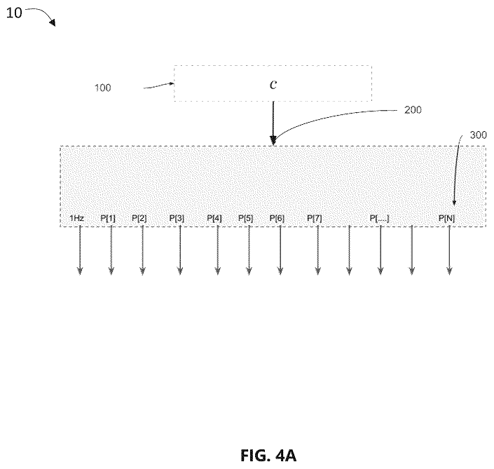

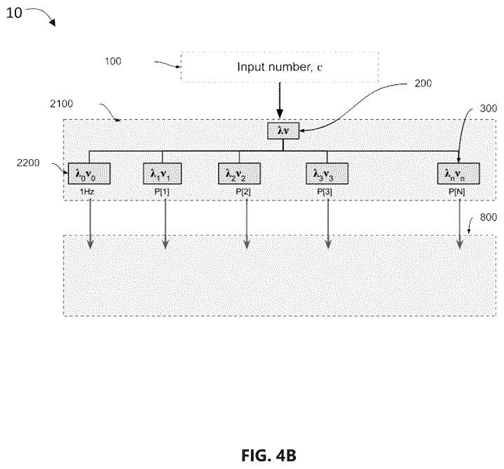

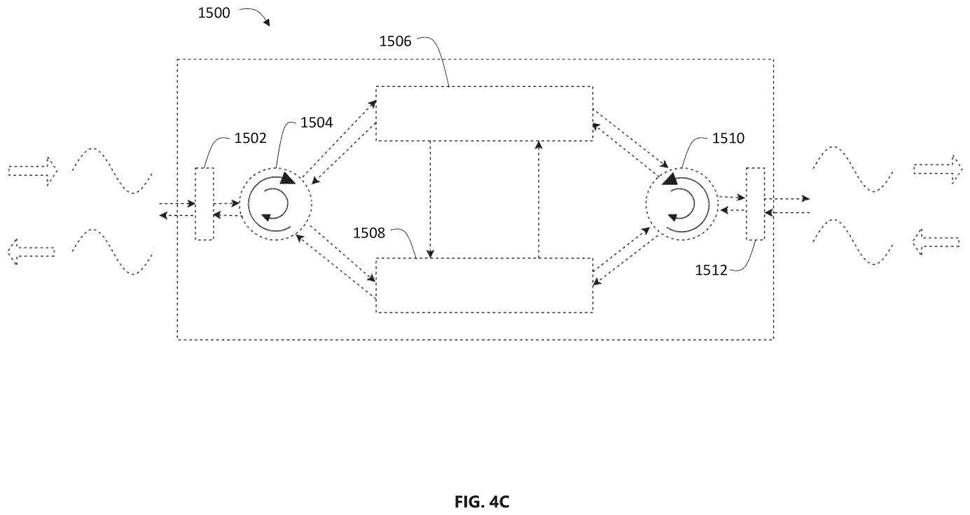

FIG. 4A is one embodiment of the wave-based computer 10 in accordance with aspects of this disclosure. In particular, this figure shows a high-level abstraction of the input to and outputs generated by the wave-based computer 10, before being recombined and output at block 1000.

FIG. 4B provides a more detailed view of the wave-based computer 10 of FIG. 4A in accordance with aspects of this disclosure. In particular, FIG. 4B illustrates the oscillators 300 included in the input circuit 20 and connected to the plurality of transmission line paths 800.

With reference to FIGS. 4A and 4B, the wave-based computer 10 includes an input controller 100 configured to generate an input waveform 200 which is provided to a plurality of oscillators 300.

In some embodiments, the input controller 100 can include a large number register configured to hold a numerical value c as illustrated by the oscillators 300. The input controller 100 is configured to convert the numerical value c, a representation of the numerical value, into the input waveform 200 (e.g., as a sinusoidal wave with a frequency corresponding to the numerical value c) in FIG. 2B. As described herein, the oscillators 300 include prime oscillators 300 with internal oscillators tuned at prime frequencies. A circuit comprising internal oscillators tuned at prime frequencies.

As described herein, the wave-based computer 10 is configured to de-synthesize a large integer, into its primes factors using a resonance process, or a reverse process allowing synthesis or reconstruction of a number based on its prime signature. Each channel 2200 outputs a sine wave for that channel, which represents the exponent power to which that factor was found within the numerical value. The channels include a 1 Hz synchronization wave and outputs for each prime factor up to the Nth prime.

Prime numbers are chosen by design, as they have no harmonics as they are only divisible by 1. Prime numbers can be considered as “anharmonic.”

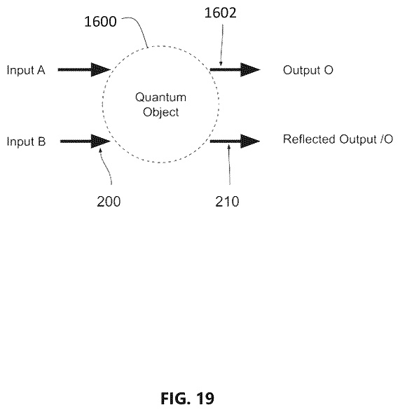

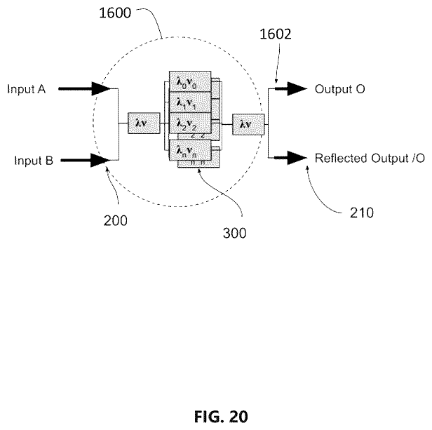

FIG. 4C illustrates a complete reactive computer system concept 1500 in accordance with aspects of this disclosure. In particular, FIG. 4C is one embodiment of a wave-based reactive computer in accordance with aspects of this disclosure, corresponding with FIG. 19 and FIG. 20. In certain embodiments, the reactive computer 1500 can be configured to absorb inputs, reflect an input, and/or use inputs in order to determine emission or transmits.

The reactive computer system 1500 may include a first impedance matching box 1502, a first three-port radio frequency (RF) circulator 1504, a first computer 1506, a second computer 1508, a second three-port RF circulator 1510, and a second impedance matching block 1512.

The first and second impedance matching boxes 1502 and 1510 may be included, for example, to reduce unwanted wave reflections at the input medium and the output medium. The first three-port RF circulator 1504 can be configured to route signals to/from the first computer 1506 and the second computer 1508. For example, the first three-port RF circulator 1504 can be configured to filter and split the sinusoidal signals (e.g., as shown in FIG. 2D). The second computer 1508 can be configured to intentionally reflect the sinusoidal signal back to the first three-port RF circulator 1504 or route the sinusoidal signals into the second three-port RF circulator 1510. The impedance matching block 1512 to reduce unwanted signal reflections in the sinusoidal signals before the sinusoidal signal leave to the exit medium.

If the reactive computer's internal switching is designed to reflect an input signal, then in reference to FIG. 4C, one or more waves can enter the reactive computer 1500 (as shown by the arrows entering the impedance matching box 1500). A wave signal may be received by the first three-port RF circulators 1504, switched internally by a pin-diode style switch (e.g., as shown in FIG. 2E) in the first computer 1506 and/or additional pin-diode switches within the second computer 1508, and then output via the original input via the first three-port RF circulators 1504.

If the reactive computer's internal switching is designed to absorb the input wave power or energy, then with reference to FIG. 4C, one or more waves can enter the reactive computer 1500. A wave signal may be received by the first three-port RF circulator 1504, decomposed into spectra 800, analyze and compute the spectra 600, and produce results via the summing junction 1000 or the user interface 1200.

In some embodiments, the wave-based computer 10 of FIGS. 4A and 4B may be located within the first computer 1506 and/or the second computer 1508 where the input number c, may be a digital value to be configured as a frequency and oscillator value then factored into individual prime components, or a wave containing a superposition of individual prime components to be factored.

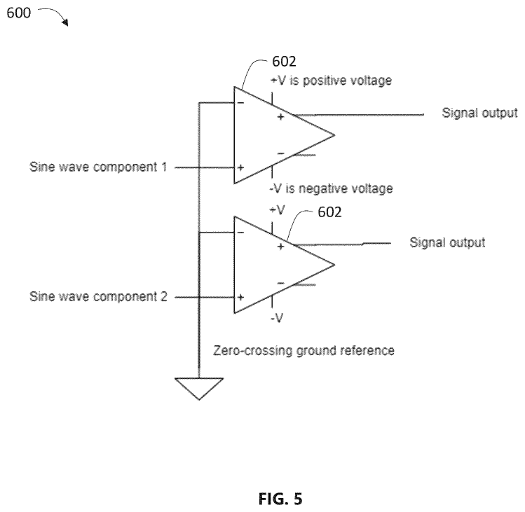

FIG. 5 is another embodiment of a zero-crossing detector 600 in accordance with aspects of this disclosure. As shown in FIG. 5, the zero-crossing detector 600 can include one or more amplifiers 602 that are configured to receive a corresponding sine wave component as an input. Each of the amplifiers 602 is configured to generate a signal output that indicates when the corresponding sine wave has a value of zero.

While zero-crossing detectors may typically output a square pulse, the zero-crossing detectors 600 according to aspects of this disclosure can be configured to output symmetric pulses, as illustrated by the response waveforms, and discussed herein.

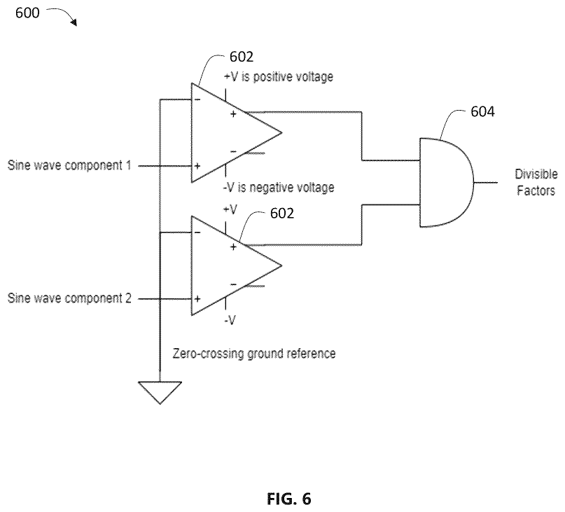

FIG. 6 is yet another embodiment of a zero-crossing detector 600 in accordance with aspects of this disclosure. As shown in FIG. 6, the zero-crossing detector 600 can include one or more amplifiers 602 that are configured to receive a corresponding sine wave component as an input and output a zero-crossing detection pulse into a logical AND gate 604. The logical AND gate 604 is configured to output divisible factor values when all of the corresponding zero-crossing detection pulses substantially simultaneously go high.

FIGS. 5 and 6 show example arrays of comparators 602. Each comparator 602 can be configured to function as a part of a zero-crossing detector 600 with an input connected to a component sine wave, and a common reference ground, such that a signal is output at the moment that the sine wave component comes within a tolerance of the zero-crossing ground reference, momentarily activating a zero-crossing signal pulse output toward +V or toward −V.

When the first sine wave component is a prime wave and the second sine wave component is the dividend wave, the logical AND gate 604 can be configured to determine that the prime number corresponding to the prime wave is a factor of the dividend in response to both amplifiers 602 outputting a response wave at substantially the same time.

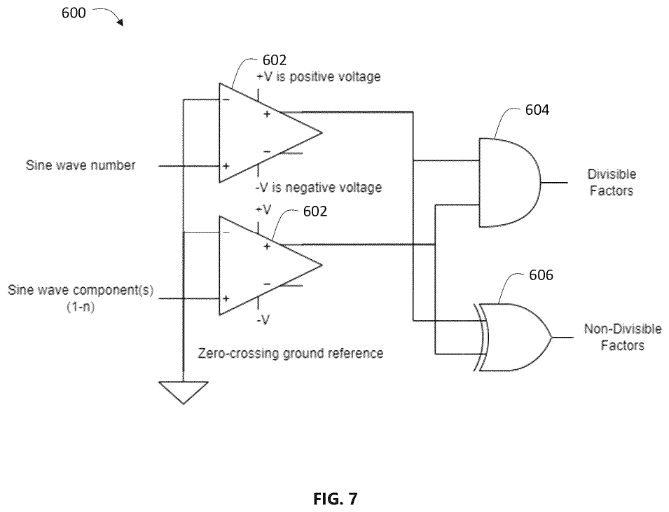

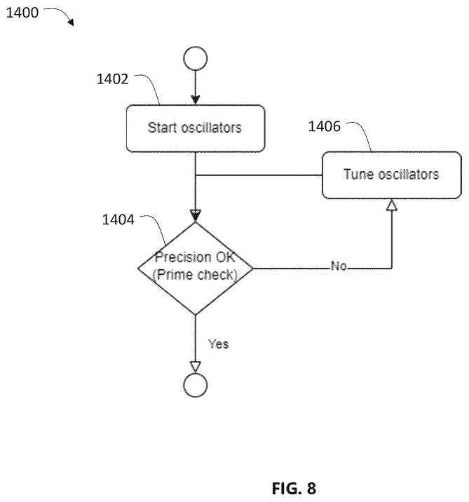

FIG. 7 is still yet another embodiment of a zero-crossing detector 600 in accordance with aspects of this disclosure. As shown in FIG. 7, the zero-crossing detector 600 can include one or more amplifiers 602 that are configured to receive a corresponding sine wave component as an input, a logical AND gate 604, and a logical exclusive OR gate 606. The logical exclusive OR gate 606 is configured to output non-divisible factor values. For example, when the amplifiers 602 output response waves at different times, the logical exclusive OR gate 606 may indicate that the prime number corresponding to a prime wave is not a factor of the dividend, and may be used in the prime check verification, for example, in block 1404 of FIG. 8.

FIG. 8 is a flowchart illustrating an example method 1400 for calibrating a wave-based computer 10 in accordance with aspects of this disclosure. In particular, the method 1400 is configured to perform calibration where no prime component waves register as crossing at the same time.

At block 1402, the method 1400 involves stating the oscillators 300. At block 1404, the method 1400 involves performing a precision check. The precision check can include passing a superposition of prime waves (e.g., see FIG. 17K) through zero-crossing detectors 600, outputting an interference pattern (e.g., as shown in FIG. 17LB), and passing each output zero-crossing detection pulse through the amplifiers 604. The precision check can further include observing the output response waves from the amplifiers 604 at different times and phases within a 1 Hz synchronization sine wave and the logical exclusive OR gate 606 may indicate that the prime number corresponding to a prime wave is not a factor of the dividend, and may be used in the prime check verification 1404. If the precision for at least one of the oscillators 300 is less than a threshold precision (“No” from block 1404), the method 1400 proceeds to block 1406. At block 1406, the method 1400 involves tuning one or more of the oscillators 300. If the precision for the oscillators 300 is greater than the threshold precision (“Yes” from block 1404), the method 1400 ends.

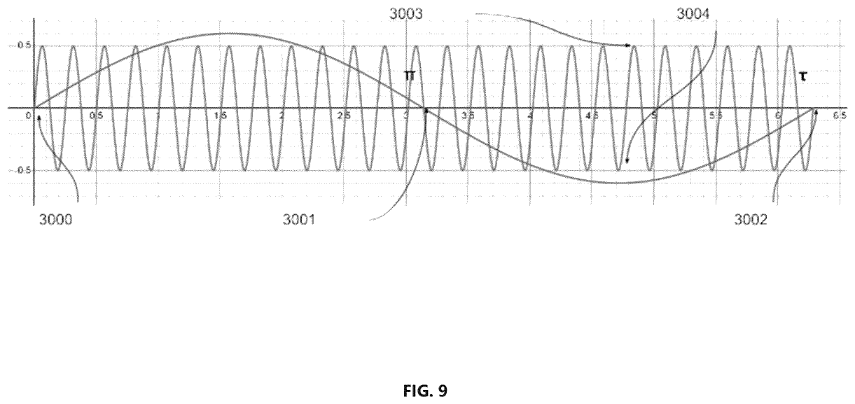

FIGS. 9-15 illustrate example waves that may be generated by example oscillators 300 when detecting the prime factors of an example dividend 3003 in accordance with aspects of this disclosure. In particular, in the embodiment of FIGS. 9-15, the dividend 3003 may be the number 25, represented by a sine wave with a frequency of 25 Hz. In each of FIGS. 9-15, the x-axis represents a full period of the synchronization wave measured in radians, for example, from 0 rad to 2π rad.

As described herein, the dividend 3003 can be factored into its prime factors by comparing zero-crossing of oscillator 300 frequency representations of the dividend 3003, against oscillator frequency representations of prime factors. Prime factors are a small percentage of all natural numbers and can represent all other numbers, so a wave-based computer 10 comprising pre-tuned prime factors may be significantly more efficient for finding the prime factors of dividends relative to the magnitude of numbers it can represent when compared with traditional digital computers.

FIG. 9 illustrates the dividend 3003 and the synchronization wave 3004 in accordance with aspects of this disclosure. The zero-crossings at a start 3000 of the synchronization wave 3004, a mid-point 3001 of the synchronization wave 3004, and an end 3002 of the synchronization wave 3004 can be used for synchronization and correspond to 0, π, and 2π radians.

Two numbers are divisible by one another if they share zero crossings, within one full period of the synchronization wave 3004, with the exception of nodes 0 3000, π 3001 and tau τ=2π 3002.

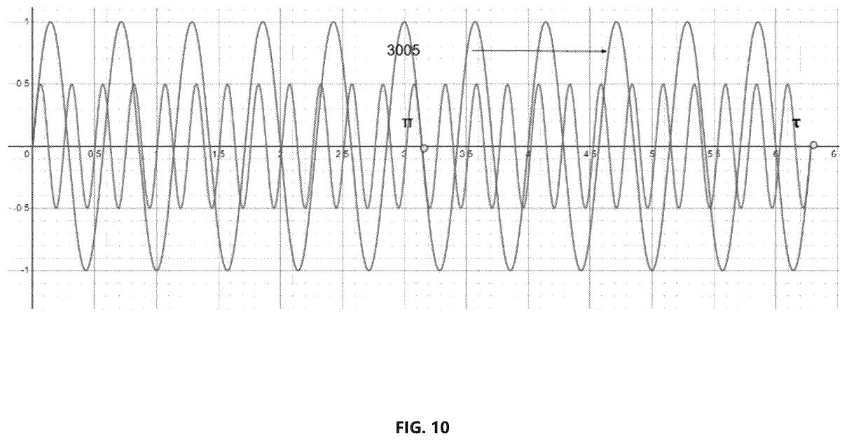

FIG. 10 shows a prime wave 3005 with a frequency of 11 Hz, representing the prime number 11. Because the zeros of prime wave 3005 and dividend 3003 do not cross (e.g., they do not occur at the same time outside of the exception nodes), the prime number 11 is not a factor of the dividend 25.

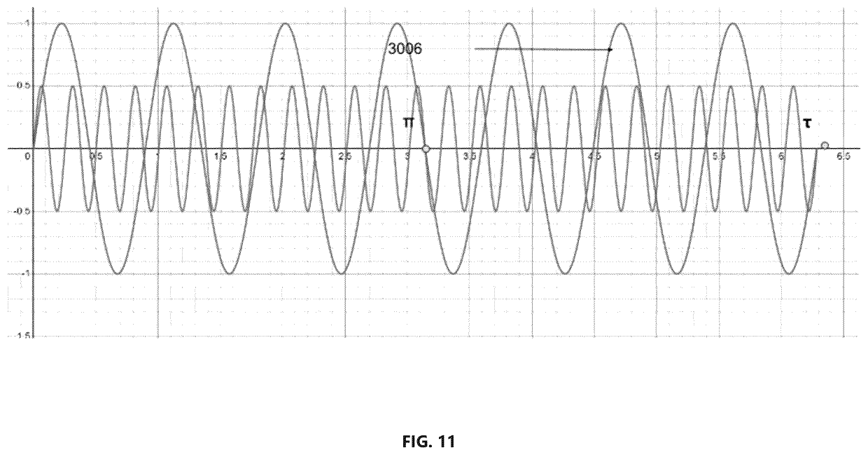

FIG. 11 shows a prime wave 3006 with a frequency of 7 Hz, representing the prime number 7. Because the zeros of prime wave 3006 and dividend 3003 do not cross (e.g., they do not occur at the same time outside of the exception nodes), the prime number 7 is not a factor of the dividend 25.

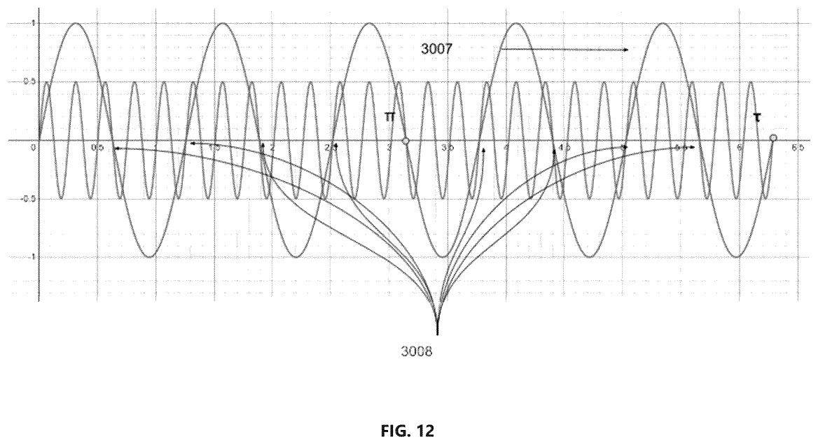

FIG. 12 shows a prime wave 3007 with a frequency of 5 Hz, representing the prime number 5. Because the zeros of prime wave 3007 and dividend 3003 cross (e.g., they occur at the same time outside of the exception nodes) at the points 3008, the prime number 5 is a factor of the dividend 25.

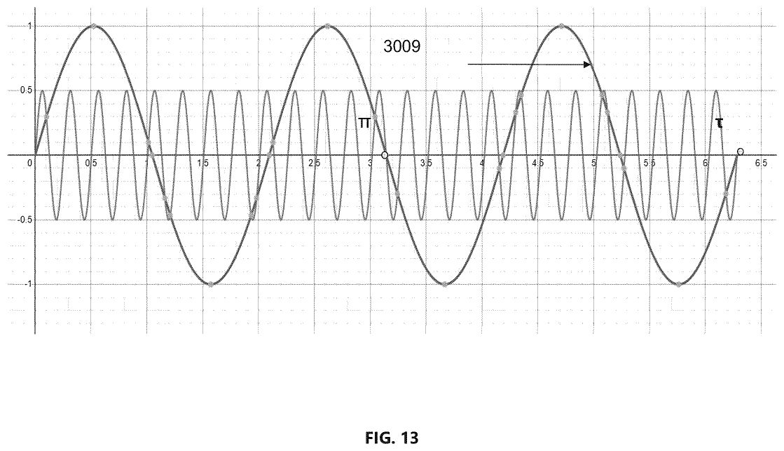

FIG. 13 shows a prime wave 3009 with a frequency of 3 Hz, representing the prime number 3. Because the zeros of prime wave 3009 and dividend 3003 do not cross (e.g., they do not occur at the same time outside of the exception nodes), the prime number 3 is not a factor of the dividend 25.

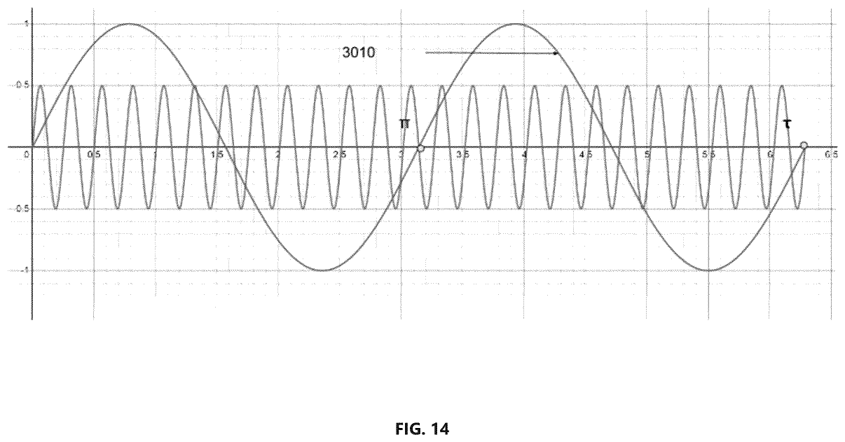

FIG. 14 shows a prime wave 3010 with a frequency of 2 Hz, representing the prime number 2. Because the zeros of prime wave 3010 and dividend 3003 do not cross (e.g., they do not occur at the same time outside of the exception nodes), the prime number 2 is not a factor of the dividend 25.

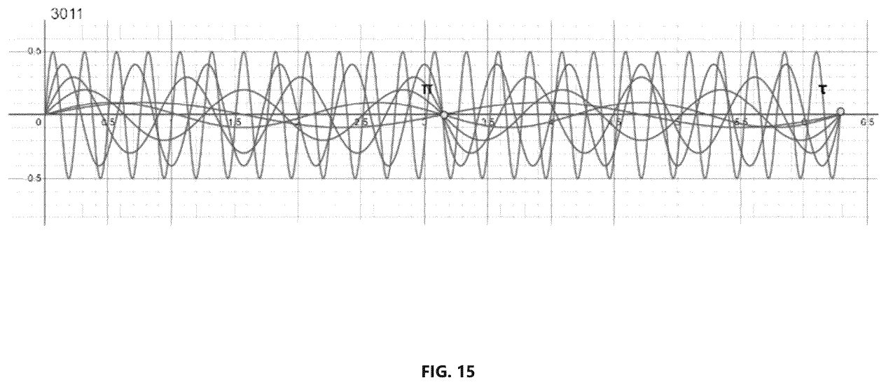

FIG. 15 illustrates the superposition of each of the individual waves 3011 from FIGS. 9-14. The superposition of all zero crossings from that of the primes, against that of the dividend, quickly reveal those which match the dividend.

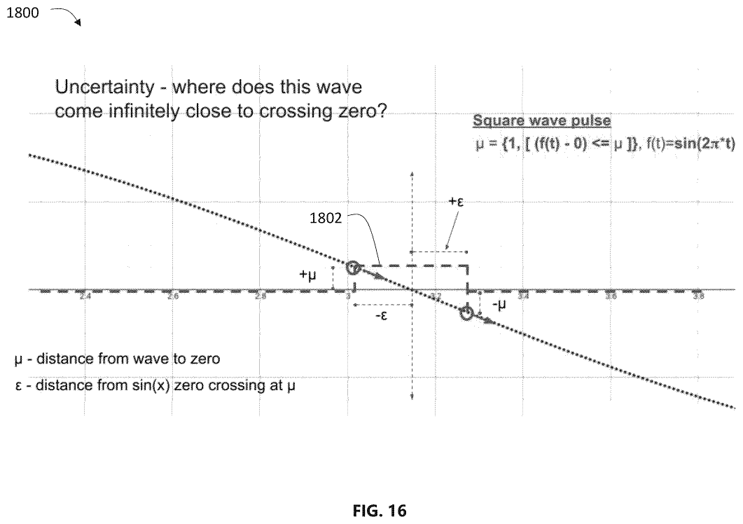

FIG. 16 illustrates measurement uncertainty associated with the detection of a zero-crossing in accordance with aspects of this disclosure. Specifically, FIG. 16 shows a section of wave 1800 from an oscillator, zoomed in, and a pulse 1802 which is output as a function of the wave's distance from the zero-crossing line. In this figure, p represents a distance in amplitude from the wave to zero and P represents the distance in time from the wave to zero.

FIGS. 17A-17O show a sinusoidal waveform with a zero-crossing detection impulse overlayed in accordance with aspects of this disclosure. The impulses may be generated by a zero-crossing detector 600. The impulse may be positive or negative to indicate frequency and phase. For example, when the wave crosses zero from a positive amplitude to a negative amplitude, the impulse may be negative and vice versa.

FIG. 17A shows a synchronization wave with a frequency of 1 Hz in accordance with aspects of this disclosure. FIGS. 17B and 17C illustrate the synchronization wave with a zero-crossing detection response waveform, which may be generated by a zero-crossing detector 600 in accordance with aspects of this disclosure. In particular, FIG. 17B shows the zero-crossing detector pulse and FIG. 17C shows the zero-crossing detector wave pulse and corresponding zero-crossing detector response particle located on and traveling along the zero-crossing line.

FIGS. 17D-17F illustrate the synchronization wave with a zero-crossing detection response waveform at a different time. In these figures, the zero-crossing detection response waveform have varying tolerance levels indicated by the width of the response waveforms.

FIGS. 17G-17J illustrate different waveforms and the corresponding zero-crossing detection response waveforms for the numbers 2, 3, 5, and 15, respectively.

FIG. 17K illustrates the zero-crossing responses for the prime numbers 1, 2, 3, and 5. FIG. 17L illustrates the zero-crossing responses for the prime numbers 1, 2, 3, and 5 without the waveforms. The prime oscillator waveforms cross zero at 0, π and 2π, but not between 0 and π, and not between π and 2π because the waveforms are prime and not divisible by one another. The response waveforms are distinctly visible.

FIG. 17M illustrates the waveforms and zero-crossing responses for the prime numbers 1, 2, 3, and 5 as well as the example dividend integer 15. FIGS. 17N and 17O illustrate the zero-crossing responses for the prime numbers 1, 2, 3, and 5 and the dividend 15 in which the response waveforms are summed together. The sum of the response waveforms with a unit magnitude of two reveals common or divisible factors. Common factors are associated with 5 Hz and 3 Hz which indicates that 15 Hz is divisible by 3 Hz and 5 Hz.

In some embodiments, when the sum of all response waveforms does not exceed 1, the wave-based computer 10 may determine that the zero-crossings are all prime and unique and have adequate precision. In contrast, when the sum of all response waveforms exceeds 1, the wave-based computer 10 may determine that the zero-crossings do not have adequate precision.

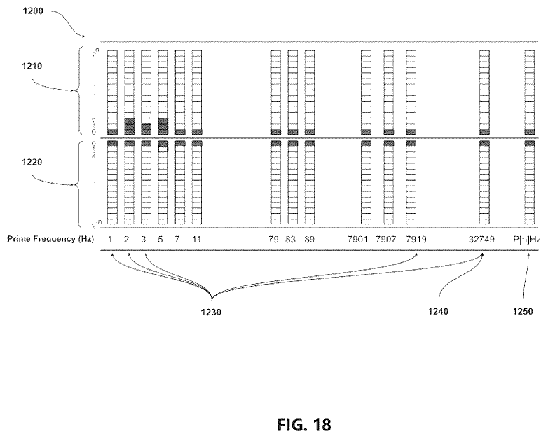

FIG. 18 illustrates a user interface 1200 for the wave-based computer 10 in accordance with aspects of this disclosure. The user interface 1200 is configured to display the results of the wave-based computer 10 which counts the presence and number of real 1210 and imaginary 1220 components across frequency 1230, up to a maximum prime frequency 1240, 1250.

In one example the prime number (e.g., the maximum prime frequency 1240) just before the maximum oscillator frequency 1250 value represented at 1230 is the prime frequency, below the common crystal oscillator frequency of 32,768 Hz.

A number with depicted by shaded area within 1210 representing a number example such as c being the product of primes, which is in the format of c=p₁ⁿ^{₁}p₂ⁿ^{₂}p₃ⁿ^{₃} . . . pₖⁿ^{ₖ}. The list of primes (p) combined with the list of exponents (n), form a unique and efficient signature for the prime factors of the input dividend integer.

### Quantum Computer Architecture

Another aspect of this disclosure is the use of a wave-based computer 10 for quantum computation. In addition to finding the prime factors of a dividend, the wave-based computer 10 can also be employed as a more general-purpose quantum computer in accordance with aspects of this disclosure.

As used herein, a quantum computer may generally refer to any computer device that uses waves properties of quantum mechanics in order to perform computations. This can be advantageous because waves have the properties of superposition, interference, and entanglement. Furthermore, particles which exhibit traits of quantum mechanics reflect, absorb, and emit waves as a function of their internal connections and impedance to incoming waves.

One challenge to implementing a quantum wave-based computer 10 is how to generate the inputs for a quantum computation. Aspects of this disclosure relate to the use of a plurality of oscillators 300 which can be used to model a quantum object.

A wave-based computing system configured to implement a quantum computing system can model or represent a quantum object or quantum wave through a governing system equation of light. In one embodiment, the governing equation has an inner product which may be as follows:

c=λ₀v₀+λ₁v₁+λ₂v₂+ . . . +λₙvₙ. (1)
where each of the λ and v components can be a reciprocal complex waveform at a unique frequency, such as a prime frequency. As used herein, the term “orthogonal” can refer to the property where prime frequencies do not contain harmonics of other prime frequencies.

In some implementations, the governing equation can be used to represent or model a quantum object, such as a charged particle, photon, poly chromatic light, human sensing, feeling, and/or emotion. For certain implementations, the oscillators 300 can be designed based on this definition of polychromatic light. As used herein, polychromatic may generally refer to simultaneously “including multiple orthogonal frequencies.” Aspects of this disclosure relate to modeling systems with multiple traits or spectra, such as light, human emotions, molecules, or abstract ideas by combining spectra into a single system.

In certain aspects, the complex waveform can be represented by two pairs of oscillators 300. The oscillators 300 may have the same or configurable frequency and relative phases. With reference to FIGS. 1B and 1C, each pair of oscillators 300 can be configured to be tuned using a corresponding input waveform 200 received from the input controller 100.

In some embodiments, the waveform generated by each pair of oscillators 300 can represent a complex number λλₐλ_{b}vvₐv_{b}. It can also be important to represent the reciprocal state, the inverse of a complex number. Thus, the oscillators 300 can include a first bank of oscillators 300 configured to generate a complex number and a second back of oscillators 300 configured to generate the reciprocal complex number. The oscillators 300 can be formed as pairs, with a first one of the pair configured to generate a complex number and the second one of the pair configured to generate the reciprocal part of the complex number to represent a quantum state or quantum digit. In some embodiments, each pair of oscillators 300 can be configured to generate waves which may be, but not limited to being out of phase by 90 degrees from each other.

With continued reference to FIGS. 1A-1C, the quantum wave-based computer 10 can include a plurality of selectable and switchable couplings 850 between the oscillators 300. These couplings 850 can be used to selectively couple any pair of oscillators 300. The plurality of transmission line paths 800 can be formed of a controlled impedance material with conductors to channel waves received from the oscillators 300. Controlling transmission line paths by controlled impedance can be used to substantially minimize signal loss, substantially minimize reflections, and ensure signal propagation through the material medium. In some embodiments, the material medium can include one or more of: copper line, nanofiber, optical fiber, and/or other material with design engineered transmission line characteristics.

With reference to FIG. 1C, the gyrators 860 can allow for conversions, such as the control of impedance between voltage medium to current medium, or voltage to negative current. This can enable the modeling of a quantum object, which includes the ability to reflect, absorb, and/or emit waves in a controlled manner. Controlling impedance allows the circuit to adjust the amount of signal which is completely reflected or absorbed and routed through the internal circuit and optionally reflected or re-transmitted. Converting the signal to current allows the signal to be measured via inductance since currents generate magnetic fields proportional to the current and without direct physical contact. Controlling impedance also allows the circuit to be isolated from the input and converted to another optional medium. Reflections can occur whenever a signal transitions from one medium to another medium. Impedance matching allows the control of such reflections which may cause undesirable effects, such as noise.

Each wave path of the transmission line paths 800 can be coupled to a node detector. In some implementations, the node detector can be embodied as a zero-crossing detector 600. As each wave crosses zero at a node, the zero-crossing detector 600 can be configured to output a signal transition or pulse. The output of each of the zero-crossing detectors 600 can be provided to or by a corresponding PLL 700. In some embodiments, the PLLs 700 can be arranged between a corresponding one of the oscillators 300 and an input wave. The pulse output from the zero-crossing detector 600 can be used as a form of feedback used to adjust oscillators in relative phase.

Once the waves are coherent (locked in phase), the wave-based computer 10 can superimpose the waves and transmit the waves through the zero-crossing detectors 600 and analog computing blocks 750 so that the analog computing blocks 750 may compute operations. The analog computing blocks 750 can be configured to compute operations such as summing the zero-crossing pulses for number factoring and/or sending the sinusoidal signals to analog computers for the purposes of, but not limited to, addition, integration, differentiation, logarithms, including trigonometric identities, multiplication, and convolution.

In order to select an analog equation for the wave-based computer 10, the input controller 100 may switch each of the input waveforms A and B 200. The input waveforms 200 can be configured to perform the desired operation on the oscillators 300 to generate a pair of waves to produce the output at the summing junction 1000.

As in the prime factoring wave-based computer 10, the phase rotators 400 can be configured to provide precise phase rotation or polarity inversion adjustment of the waveforms output from each of the oscillators 300 in order to ensure that the waveforms are synchronized to within a threshold value.

In some embodiments, the reactive computer model in FIG. 4C may simulate a quantum particle at the inputs and outputs via its signal models for S-parameters and S-transfer parameters.

In the context of the quantum wave-based computer 10, the summing junction 1000 can be configured to provide a wavefunction summation or product. This can enable the wave-based computer 10 to provide an output to a given quantum computation based on the input signals A and B.

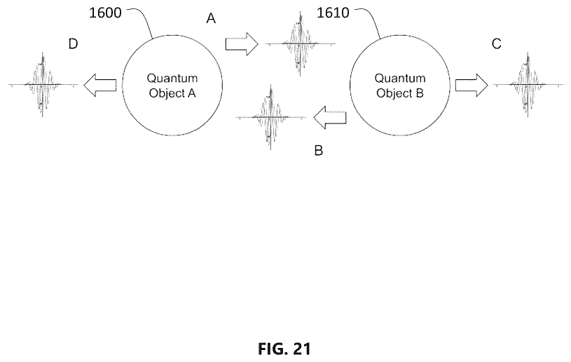

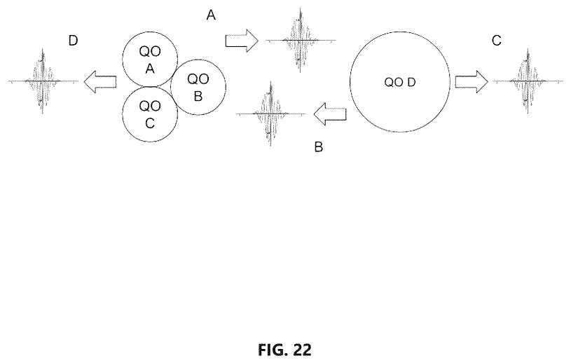

FIGS. 19-22 illustrate aspects of a quantum object 1600 in accordance with aspects of this disclosure. In particular, FIG. 19 illustrates a quantum object 1600 which can receive a pair of input waveforms 200, and generate an output 1602, and a reflected output 210. In more detail, FIG. 19 illustrates a quantum object which can receive a pair of input waveforms which contain spectra, absorb some of the waveform spectra, generate an output spectra, and reflect a portion of the output spectra. This input and output may be modeled with S-parameters and S-transfer parameters. FIG. 20 illustrates a more detailed embodiment of the quantum object 1600 including a plurality of oscillators 300. FIG. 21 illustrates how a first quantum object 1600 and a second quantum object 1610 can interact. FIG. 22 illustrates the internal states of the first quantum object 1600 from the interaction illustrated in FIG. 21.

With reference to FIGS. 19-22, a quantum object 1600 may receive a pair of input waveforms 200, and generate an output 1602, and a reflected output 210. As used herein, a quantum object 1600 may be an object that can model particles which reflect, absorb, and/or transmit waveforms to simulate materials such as crystalline structures. The quantum object may be modeled by one or more oscillators 300 which represent a reference state which is contained within the quantum object and can be used as a comparison against incoming signals. In some embodiments, a quantum object 1600 can be configured to model reactions present in one or more living organisms and/or simulate materials as crystalline structures.

As shown in FIG. 20, the quantum object 1600 can include one or more internal oscillators 300 configured to respond to external waves, such as the input waveform 200. The oscillators 300 may further be configured to represent one or more quantum states. For example, the oscillators 300 can represent a reference state contained within the quantum object and used as a comparison against incoming signals. In some cases, the input waveform 200 may be generated by another quantum object as shown in FIG. 21.

FIG. 21 also shows how waves can be exchanged between two quantum particles, for example, the first quantum object 1600 and the second quantum object 1610. FIG. 22 illustrates an embodiment showing collections of quantum objects. FIG. 4C illustrates the electronic block diagram implementation of what is occurring within each quantum object.

In some embodiments, the input waveform 200, the output 1602, and the reflected output 210 may each be wavelets and/or steady state, and can be considered inputs and outputs to the system.

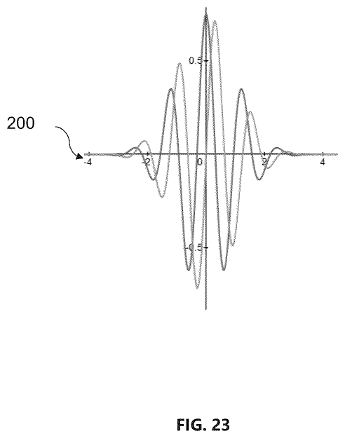

FIG. 23 illustrates an example of wave pulse oscillation (“wavelet”) containing a real and imaginary part, which can be employed as the reflected output 210, the output 1602, and/or the reflected output 210 in accordance with aspects of this disclosure. The wavelet of FIG. 23 may be generated by the summing junction 1000 and/or within the plurality of optional analog computing blocks 750 by summing two or more quantum objects generated by the inputs A and B in conjunction with the oscillators 300.

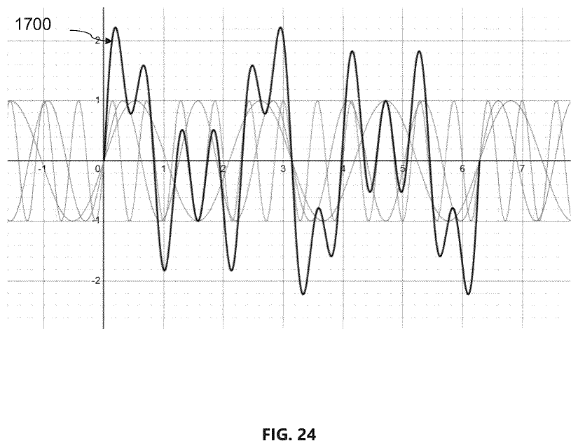

FIG. 24 shows an example of three component steady state sine waves and their summation or superposition, represented by the line 1700.

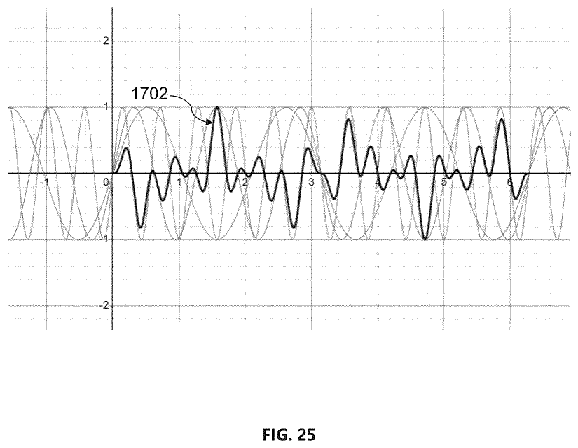

FIG. 25 shows an example of three component steady state sine waves and their multiplication or product, represented by the line 1702. A Gilbert cell is one example of a two-input differential amplifier which produces an output which is proportional to the inputs.

### Other Variations

The foregoing description details certain embodiments of the systems, devices, and methods disclosed herein. It will be appreciated, however, that no matter how detailed the foregoing appears in text, the systems, devices, and methods can be practiced in many ways. The use of particular terminology when describing certain features or aspects of the disclosure should not be taken to imply that the terminology is being redefined herein to be restricted to including any specific characteristics of the features or aspects of the technology with which that terminology is associated.

It will be appreciated by those skilled in the art that various modifications and changes can be made without departing from the scope of the described technology. Such modifications and changes are intended to fall within the scope of the embodiments. It will also be appreciated by those of skill in the art that parts included in one embodiment are interchangeable with other embodiments; one or more parts from a depicted embodiment can be included with other depicted embodiments in any combination. For example, any of the various components described herein and/or depicted in the figures can be combined, interchanged, or excluded from other embodiments.

With respect to the use of substantially any plural and/or singular terms herein, those having skill in the art can translate from the plural to the singular and/or from the singular to the plural as is appropriate to the context and/or application. The various singular/plural permutations can be expressly set forth herein for sake of clarity.

Directional terms used herein (for example, top, bottom, side, up, down, inward, outward, etc.) are generally used with reference to the orientation or perspective shown in the figures and are not intended to be limiting. For example, positioning “above” described herein can refer to positioning below or on one of sides. Thus, features described as being “above” may be included below, on one of sides, or the like.

It will be understood by those within the art that, in general, terms used herein are generally intended as “open” terms (for example, the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims can contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (for example, “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (for example, the bare recitation of “two recitations,” without other modifiers, typically means at least two recitations, or two or more recitations).

The term “comprising” as used herein is synonymous with “including,” “containing,” or “characterized by,” and is inclusive or open-ended and does not exclude additional, unrecited elements or method steps.

Conditional language, such as “can,” “could,” “might,” or “may,” unless specifically stated otherwise, or otherwise understood within the context as used, is generally intended to convey that certain embodiments include, while other embodiments do not include, certain features, elements, and/or steps. Thus, such conditional language is not generally intended to imply that features, elements, and/or steps are in any way required for one or more embodiments or that one or more embodiments necessarily include logic for deciding, with or without user input or prompting, whether these features, elements, and/or steps are included or are to be performed in any particular embodiment.

Language of degree used herein, such as the terms “approximately,” “about,” “generally,” and “substantially” as used herein represent a value, amount, or characteristic close to the stated value, amount, or characteristic that still performs a desired function and/or achieves a desired result. For example, the terms “approximately”, “about”, “generally,” and “substantially” may refer to an amount that is within less than 10% of, within less than 5% of, within less than 1% of, within less than 0.1% of, and/or within less than 0.01% of the stated amount.

It will be further understood by those within the art that any disjunctive word and/or phrase presenting two or more alternative terms, whether in the description, claims, or drawings, can be understood to contemplate the possibilities of including one of the terms, either of the terms, or both terms. For example, the phrase “A or B” will be understood to include the possibilities of “A” or “B” or “A and B.” Further, the term “each,” as used herein, in addition to having its ordinary meaning, can mean any subset of a set of elements to which the term “each” is applied.

Conjunctive language such as the phrase “at least one of X, Y, and Z,” unless specifically stated otherwise, is otherwise understood with the context as used in general to convey that an item, term, etc. may be either X, Y, or Z. Thus, such conjunctive language is not generally intended to imply that certain embodiments require the presence of at least one of X, at least one of Y, and at least one of Z.

The various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. The described functionality may be implemented in varying ways for each particular application, but such implementation decisions should not be interpreted as causing a departure from the scope of the embodiments of the invention.

The various illustrative blocks, modules, and circuits described in connection with the embodiments disclosed herein may be implemented or performed with a general-purpose processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm and functions described in connection with the embodiments disclosed herein may be embodied directly in hardware, in a software module executed by a processor, or in a combination of the two. If implemented in software, the functions may be stored on or transmitted over as one or more instructions or code on a tangible, non-transitory computer-readable medium. A software module may reside in Random Access Memory (RAM), flash memory, Read Only Memory (ROM), Electrically Programmable ROM (EPROM), Electrically Erasable Programmable ROM (EEPROM), registers, hard disk, a removable disk, a CD ROM, or any other form of storage medium known in the art. A storage medium is coupled to the processor such that the processor can read information from, and write information to, the storage medium. In the alternative, the storage medium may be integral to the processor. Disk and disc, as used herein, includes compact disc (CD), laser disc, optical disc, digital versatile disc (DVD), floppy disk and blu ray disc where disks usually reproduce data magnetically, while discs reproduce data optically with lasers. Combinations of the above should also be included within the scope of computer readable media. The processor and the storage medium may reside in an ASIC. The ASIC may reside in a user terminal. In the alternative, the processor and the storage medium may reside as discrete components in a user terminal.

The above description discloses embodiments of systems, apparatuses, devices, methods, and materials of the present disclosure. This disclosure is susceptible to modifications in the components, parts, elements, steps, and materials, as well as alterations in the fabrication methods and equipment. Such modifications will become apparent to those skilled in the art from a consideration of this disclosure or practice of the disclosure. Consequently, it is not intended that the disclosure be limited to the specific embodiments disclosed herein, but that it cover all modifications and alternatives coming within the scope and spirit of the subject matter embodied in the following claims.

What is claimed is:

1. A wave-based computer, comprising:
an input circuit configured to receive a dividend and generate a plurality of prime waves and a dividend wave based on the received dividend;
a transmission circuit configured to receive the prime waves and the dividend wave from the input circuit; and
an output circuit configured to:
receive the prime waves and the dividend wave from the transmission circuit,
detect zero-crossings of each of the prime waves and the dividend wave, and
determine prime factors of the dividend based on the detected zero-crossings.

2. The computer of claim 1, wherein the input circuit comprises:
a plurality of prime oscillators, each of the prime oscillators configured to generate a corresponding one of the prime waves having a frequency corresponding to a prime number, and
a dividend oscillator configured to be tuned to generate the dividend wave to have a frequency that corresponds to the dividend.

3. The computer of claim 2, wherein the input circuit further comprises:
a plurality of phase adjustors configured to adjust a phase of a corresponding one of the prime oscillators and the dividend oscillator.

4. The computer of claim 3, wherein adjusting the phase of the corresponding one of the prime oscillators and the dividend oscillator comprises rotating or inverting the phase.

5. The computer of claim 2, wherein the transmission circuit comprises:
a plurality of transmission line paths, each of the transmission line paths including a conductive path that couples a corresponding one of the prime oscillators and the dividend oscillator to the output circuit.

6. The computer of claim 5, wherein the transmission circuit further comprises:
a plurality of gyrators, each of the gyrators configured to convert a corresponding one of the prime waves and the dividend waves from a voltage wave to a current wave.

7. The computer of claim 5, wherein the output circuit comprises:
a plurality zero-crossing detectors configured to receive a corresponding one of the prime waves and the dividend wave and generate a zero-crossing signal indicating that the corresponding one of the prime waves and the dividend wave has a value of substantially zero.

8. The computer of claim 7, wherein each of the zero-crossing signals has a predetermined shape including one or more of the following: a rectangular pulse, a cosine squared pulse, a Dirac pulse, a sinc pulse, a Ricker pulse, a hypergeometric pulse, or a Gaussian pulse.

9. The computer of claim 7, wherein the output circuit further comprises:
a plurality of registers, each of the registers configured to receive a corresponding one of the zero-crossing signals and increment a value in the register in response to the received zero-crossing signal.

10. The computer of claim 9, wherein the output circuit is further configured to determine the prime factors of the dividend based on a first one of the registers corresponding to a prime wave incrementing at substantially the same time as a second one of the registers corresponding to the dividend wave incrementing.

11. A method for quantum computation comprising:
receiving an input dividend integer;
generating a dividend wave using a dividend oscillator, the dividend wave having a frequency that represents the input dividend integer;
generating a plurality of prime waves using a plurality of prime oscillators, each of the prime waves having a frequency that represents a corresponding prime number;
detecting, using a plurality of zero-crossing detectors, zero-crossings of the dividend wave and each of the prime waves; and
determining prime factors of the dividend integer based on the detected zero-crossings.

12. The method of claim 11, further comprising:
adjusting, using a plurality of phase adjustors, a phase of each of the dividend wave and the prime waves.

13. The method of claim 11, further comprising:
transmitting the dividend wave and each of the prime waves to the zero-crossing detectors using a plurality of transmission line paths.

14. The method of claim 11, further comprising:
converting the dividend wave and each of the prime waves from a voltage wave to a current wave using a plurality of gyrators.

15. The method of claim 11, further comprising:
generating, using the zero-crossing detectors, a zero-crossing signal indicating that the corresponding one of the prime waves and the dividend wave has a value of substantially zero.

16. The method of claim 15, wherein each of the zero-crossing signals has a predetermined shape including one or more of the following: a rectangular pulse, a cosine squared pulse, a Dirac pulse, a sinc pulse, a Ricker pulse, a hypergeometric pulse, or a Gaussian pulse.

17. A non-transitory computer readable recording medium comprising instructions, when executed by a wave-based computer, cause the wave-based computer to:
receive an input dividend integer;
generate a dividend wave using a dividend oscillator, the dividend wave having a frequency that represents the input dividend integer;
generate a plurality of prime waves using a plurality of prime oscillators, each of the prime waves having a frequency that represents a corresponding prime number;
detect, using a plurality of zero-crossing detectors, zero-crossings of the dividend wave and each of the prime waves; and
determine prime factors of the dividend integer based on the detected zero-crossings.

18. The non-transitory computer readable recording medium of claim 17, wherein the instructions further cause the wave-based computer to:
adjust, using a plurality of phase adjustors, a phase of each of the dividend wave and the prime waves.

19. The non-transitory computer readable recording medium of claim 17, wherein the instructions further cause the wave-based computer to:
transmit the dividend wave and each of the prime waves to the zero-crossing detectors using a plurality of transmission line paths.

20. The non-transitory computer readable recording medium of claim 17, wherein the instructions further cause the wave-based computer to:
convert the dividend wave and each of the prime waves from a voltage wave to a current wave using a plurality of gyrators.

21. The non-transitory computer readable recording medium of claim 17, wherein the instructions further cause the wave-based computer to:
generate, using the zero-crossing detectors, a zero-crossing signal indicating that the corresponding one of the prime waves and the dividend wave has a value of substantially zero.

22. A wave-based computer, comprising:
an input signal processor configured to receive a dividend and generate a plurality of prime waves and a dividend wave based on the received dividend;
a transmission circuit configured to receive the prime waves and the dividend wave from the input signal processor; and
an output signal processor configured to:
receive the prime waves and the dividend wave from the transmission circuit,
detect zero-crossings of each of the prime waves and the dividend wave, and
determine prime factors of the dividend based on the detected zero-crossings.
